(19) United States
(12) Patent Application Publication
(10) Pub. No.: US 2014/0118579 A1
(43) Pub. Date: May 1, 2014

(54) IMAGE PROCESSING APPARATUS AND IMAGE PROCESSING METHOD

(71) Applicants: TAE-CHAN KIM, YONGIN-SI (KR); BYUNG-JOON BAEK, GOYANG-SI (KR); DONG-JAE LEE, OSAN-SI (KR)

(72) Inventors: TAE-CHAN KIM, YONGIN-SI (KR); BYUNG-JOON BAEK, GOYANG-SI (KR); DONG-JAE LEE, OSAN-SI (KR)

(21) Appl. No.: 13/963,606

(22) Filed: Aug. 9, 2013

(30) Foreign Application Priority Data
Oct. 31, 2012 (KR) 10-2012-0122561

(51) Int. Cl. H04N 9/64

(52) U.S. Cl. CPC H04N 9/646
USPC 348/242

(57) ABSTRACT

An image processing apparatus includes a first pixel, a digitization unit, and a correction unit. The first pixel includes a first photoelectric conversion layer for outputting a first electrical signal in response to received incident light, including light of a first color, light of a second color, and light of a third color; and a second photoelectric conversion layer disposed under the first photoelectric conversion layer and for outputting a second electrical signal in response to light transmitted through the first photoelectric conversion layer. The digitization unit generates first original data by digitizing the first electrical signal and generates second original data by digitizing the second electrical signal. The correction unit generates first corrected data corresponding to the light of the first color and second corrected data corresponding to the light of the second color, by respectively correcting the first original data and the second original data.

### CROSS-REFERENCE TO RELATED APPLICATION

This application claims the benefit of Korean Patent Application No. 10-2012-0122561, filed on Oct. 31, 2012 in the Korean Intellectual Property Office, the disclosure of which is incorporated herein in its entirety by reference.

### BACKGROUND

The inventive concept relates to an image sensor and peripheral circuits thereof, and more particularly, to an image processing apparatus and an image processing method capable of correcting a plurality of color data output from an image sensor having a multilayer structure.

An image sensor having a multilayer structure in which photoelectric conversion layers for absorbing light of different wavelengths and outputting electrical signals has been suggested. By stacking photoelectric conversion layers to form a multilayer structure, in comparison to an image sensor having a horizontal structure and having the same area, a high-definition image may be obtained. However, since light has various absorption-spectroscopic characteristics after passing through photoelectric conversion layers, color data output from an image sensor having the multilayer structure has a problem of color space distortion.

### SUMMARY

The inventive concept provides an image processing apparatus and an image processing method capable of correcting color space distortion generated by an image sensor having a multilayer structure.

According to an aspect of the inventive concept, there is provided an image processing apparatus including a first pixel including a first photoelectric conversion layer for outputting a first electrical signal in response to incident light, including light of a first color, light of a second color, and light of a third color; and a second photoelectric conversion layer disposed under the first photoelectric conversion layer and for outputting a second electrical signal in response to light transmitted through the first photoelectric conversion layer; a digitization unit for generating first original data by digitizing the first electrical signal and generating second original data by digitizing the second electrical signal; and a correction unit for generating first corrected data corresponding to the light of the first color and second corrected data corresponding to the light of the second color, by respectively correcting the first original data and the second original data.

The image processing apparatus may further include an interpolation unit for generating interpolation data corresponding to the light of the third color by using a color interpolation method, and thus generating pixel data of the first pixel having the first corrected data, the second corrected data, and the interpolation data.

The image processing apparatus may further include a signal processing unit for performing image processing on the first corrected data, the second corrected data, and the interpolation data of the first pixel.

The correction unit may generate the first corrected data and the second corrected data by multiplying the first original data and the second original data by a color correction matrix of size 2×2. Coefficients of the color correction matrix may be stored in a non-volatile memory, and may be variable, programmable or selectable by a user.

The image processing apparatus may further include a pixel array including the first pixel, and coefficients of the color correction matrix may vary according to a location of the first pixel within the pixel array.

Coefficients of the color correction matrix may be determined in such a way that, when monochromatic light of the first color is incident on the first pixel, the second corrected data has a value 0, and that, when monochromatic light of the second color is incident on the first pixel, the first corrected data has a value 0.

Diagonal components of the color correction matrix may have a value 1.

The first corrected data may be determined as a sum of: (1) a product of the first original data and a first coefficient, (2) a product of the second original data, and (3) a second coefficient, and a third coefficient, and the second corrected data may be determined as a sum of: (1) a product of the first original data and a fourth coefficient, (2) a product of the second original data and a fifth coefficient, and (3) a sixth coefficient.

The first photoelectric conversion layer may include an organic material for absorbing the light of the first color more than the light of the second color and the light of the third color.

The second photoelectric conversion layer may include an organic material for absorbing the light of the second color more than the light of the first color and the light of the third color.

The first pixel further may include a color filter layer between the first photoelectric conversion layer and the second photoelectric conversion layer for transmitting only the light of the second color, and the second photoelectric conversion layer may include a photo diode in a semiconductor substrate.

The second photoelectric conversion layer may include a PN junction structure formed at a first depth from a surface of a semiconductor substrate, and the first depth may be determined according to a depth to which the light of the second color is absorbed into the semiconductor substrate.

The image processing apparatus may further include a second pixel including a third photoelectric conversion layer for outputting a third electrical signal by receiving the incident light; and a fourth photoelectric conversion layer disposed under the third photoelectric conversion layer and for outputting a fourth electrical signal in response to light transmitted through the third photoelectric conversion layer, the digitization unit may generate third original data by digitizing the third electrical signal and generates fourth original data by digitizing the fourth electrical signal, the correction unit may generate third corrected data and fourth corrected data by respectively correcting the third original data and the fourth original data, and the third corrected data may be data corresponding to the light of the first color, and the fourth corrected data is data corresponding to the light of the third color. The image apparatus may further include a pixel array in which a plurality of the first pixels and a plurality of the second pixels are alternately aligned. The image apparatus may further include an interpolation unit for generating first interpolation data of the first pixel by using the fourth corrected data of the second pixels adjacent to the first pixel, and generating second interpolation data of the second pixel by using the second corrected data of the first pixels adjacent to the second pixel, and the first interpolation data may correspond to the light of the third color and the second interpolation data may correspond to the light of the second color.

The first color may be green, and one of the second color and the third color may be red and another may be blue.

According to another aspect of the inventive concept, there is provided an image processing method including receiving two electrical signals from a pixel, the pixel including two photoelectric conversion layers stacked on one another; generating two original data by digitizing the two electrical signals; converting the two original data into first corrected data and second corrected data respectively corresponding to light of a first color and light of a second color, wherein the light of the first color and the light of the second color are incident on the pixel; and generating interpolation data corresponding to light of a third color by using a color interpolation method, and thus generating pixel data of the pixel having the first corrected data, the second corrected data, and the interpolation data.

The pixel data of the pixel may be generated after the two original data are converted into the first corrected data and the second corrected data.

The image processing method may further include generating first color data, second color data, and third color data by performing color calibration on the first corrected data, the second corrected data, and the interpolation data of the pixel.

According to another aspect of the inventive concept, there is provided an image processing apparatus including a pixel including a first photoelectric conversion layer for outputting a first electrical signal in response to incident light including light of a first color, light of a second color, and light of a third color; a second photoelectric conversion layer disposed under the first photoelectric conversion layer and for outputting a second electrical signal in response to light transmitted through the first photoelectric conversion layer; and a third photoelectric conversion layer disposed under the second photoelectric conversion layer and for outputting a third electrical signal in response to light transmitted through the second photoelectric conversion layer; a digitization unit for generating first original data by digitizing the first electrical signal, generating second original data by digitizing the second electrical signal, and generating third original data by digitizing the third electrical signal; and a correction unit for generating first corrected data corresponding to the light of the first color, second corrected data corresponding to the light of the second color, and third corrected data corresponding to the light of the third color, by respectively correcting the first original data, the second original data, and the third original data.

According to another aspect of the inventive concept, there is provided an image processing method including receiving three electrical signals from a pixel, the pixel including three photoelectric conversion layers stacked on one another; generating three original data by digitizing the three electrical signals; and converting the three original data into first corrected data, second corrected data, and third corrected data respectively corresponding to light of a first color, light of a second color, and light of a third color, wherein the light of the first color, the light of the second color, and the light of the third color are incident on the pixel.

The converting may include converting the three original data into three temporary data by using a first color correction matrix; reducing noise of the three temporary data; and converting the noise-reduced three temporary data into the first corrected data, the second corrected data, and the third corrected data by using a second color correction matrix.

Diagonal components of the first color correction matrix may have values equal to or greater than 1 and equal to or less than 1.5. Also, absolute values of non-diagonal components of the first color correction matrix may be equal to or less than 0.8.

The image processing method may further include storing the first corrected data, the second corrected data, and the third corrected data in a memory of an image signal processor (ISP).

According to another aspect of the inventive concept, there is provided an image processing apparatus including a pixel array including pixels aligned in rows and columns; a data output unit for sequentially outputting original pixel data corresponding to outputs of the pixels of the pixel array by scanning the pixels in a raster scan method; a correction unit for sequentially generating corrected pixel data by using the original pixel data. Each of the pixels may include a first photoelectric conversion layer for outputting a first electrical signal by receiving incident light including light of a first color, light of a second color, and light of a third color; and a second photoelectric conversion layer disposed under the first photoelectric conversion layer and for outputting a second electrical signal by receiving light transmitted through the first photoelectric conversion layer. The original pixel data may include first original data and second original data generated by respectively digitizing the first electrical signal and the second electrical signal. The correction unit may generate the corrected pixel data including first corrected data corresponding to the light of the first color, and second corrected data corresponding to the light of the second color, based on the first original data and the second original data.

According to another aspect of the inventive concept, there is provided an apparatus, comprising: an array of light-sensing pixels, a digitization unit, and a correction unit. At least a first one of the light-sensing pixels comprises: at least a first layer and a second layer stacked on each other in a direction in which the light-sensing pixel is configured for light to impinge thereon. The first layer is configured to output a first electrical signal in response to the light impinging on the light-sensing pixel, and the second layer is configured to output a second electrical signal in response to light passing through the first layer. The first layer has a greater light absorption response in a first wavelength range than in second and third wavelength ranges, and the second layer has a greater light absorption response in the second wavelength range than in the first and third wavelength ranges. The digitization unit is configured to generate first digital data in response to the first electrical signal and to generate second digital data in response to the second electrical signal. The correction unit is configured to process the first and second digital data to at least partially compensate for contributions of light in the second and third wavelength ranges to the first electrical signal and first digital data, and to at least partially compensate for contributions of light in the first and third wavelength ranges to the second electrical signal and second digital data, and further configured to output first corrected data corresponding to light in the first wavelength range and second corrected data corresponding to light in the second wavelength range.

The first one of the light-sensing pixels may further comprise a third layer stacked beneath the first layer and second layer in the direction in which light impinges on the light-sensing pixel, wherein the third layer is configured to output a third electrical signal in response to light passing through the first and second layers, wherein the third layer has a greater light absorption response in the third wavelength range than in first and second wavelength ranges. The digitization unit may be further configured to generate third digital data in response to the third electrical signal; and the correction unit may be further configured to process the first, second and third digital data to at least partially compensate for contributions of light in the first and second wavelength ranges to the third electrical signal and third digital data, and to output third corrected data corresponding to light in the third wavelength range.

The apparatus may further comprise an image signal processor configured to process the first, second, and third corrected data to perform at least one of hue adjustment, saturation adjustment, brightness adjustment, correction of color distortion due to lighting, and white balance adjustment to the first, second, and third corrected data.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of an embodiment of an image processing apparatus;

FIG. 2 is a graph exemplarily showing optical absorption characteristics of each photoelectric conversion layer in a pixel having a structure in which three photoelectric conversion layers are stacked on one another in a direction in which the light impinges on the pixel;

FIGS. 3A through 3D are diagrams for describing an example operation of an embodiment of the correction unit illustrated in FIG. 1;

FIG. 4 is a block diagram of another embodiment of an image processing apparatus;

FIG. 5 is a block diagram of a system including an image processing apparatus;

FIG. 6 is a cross-sectional diagram of pixels of an image processing apparatus;

FIGS. 7A through 7C are diagrams showing example alignments of pixels of an image processing apparatus;

FIGS. 8A through 8C are cross-sectional diagrams of example embodiments of pixels of an image processing apparatus;

FIG. 9 is a block diagram of an example embodiment of a correction unit of an image processing apparatus;

FIG. 10 is a flowchart of an image processing method;

FIG. 11 is a block diagram of another embodiment of an image processing apparatus;

FIGS. 12A through 12D are diagrams for describing an example operation of an embodiment of the correction unit illustrated in FIG. 11;

FIG. 13 is a block diagram of an embodiment of the correction unit illustrated in FIG. 11;

FIGS. 14A through 14E are cross-sectional diagrams of example embodiments of pixels illustrated in FIG. 11;

FIG. 15 is a flowchart of another embodiment of an image processing method;

FIG. 16A is a block diagram of an embodiment of an image processing apparatus;

FIG. 16B is a block diagram of another embodiment of an image processing apparatus; and

FIG. 17 is a block diagram of another embodiment of an image processing apparatus.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the concept of the inventive concept to one of ordinary skill in the art. It should be understood, however, that there is no intent to limit exemplary embodiments of the inventive concept to the particular forms disclosed, but conversely, exemplary embodiments of the inventive concept are to cover all modifications, equivalents, and alternatives falling within the spirit and scope of the inventive concept.

In the drawings, like reference numerals denote like elements, and the sizes or thicknesses of elements may be exaggerated for clarity of explanation.

The terminology used herein is for the purpose of describing particular embodiments and is not intended to limit the inventive concept. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. It will be understood that, although the terms “first”, “second”, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of exemplary embodiments.

Unless defined differently, all terms used in the description including technical and scientific terms have the same meaning as generally understood by one of ordinary skill in the art. Terms as defined in a commonly used dictionary should be construed as having the same meaning as in an associated technical context, and unless defined in the description, the terms are not ideally or excessively construed as having formal meaning.

Hereinafter, the inventive concept will be described in detail by explaining embodiments of the inventive concept with reference to the attached drawings.

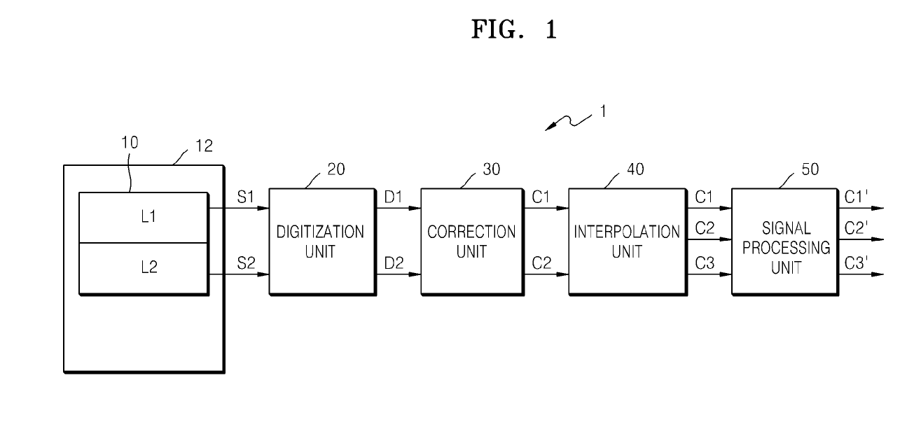

FIG. 1 is a block diagram of an image processing apparatus 1.

Referring to FIG. 1, image processing apparatus 1 includes pixels 10, a digitization unit 20, and a correction unit 30. As illustrated in FIG. 1, image apparatus 1 may further include an interpolation unit 40 and a signal processing unit 50.

Image processing apparatus 1 may include a pixel array 12 including pixels 10. In the pixel array 12, pixels 10 may be aligned in an array of rows and columns Pixel array 12 may include pixels 10 of the same type, or may include pixels of different types.

Light incident on pixels 10 is converted through an optical lens into electrical signals that are then output from pixels 10. In general, light has various wavelengths. For example, light may include not only visible light but also infrared light or ultraviolet light. In the description to follow, it is assumed that the light includes light of a first color, light of a second color, and light of a third color. For example, the light of the first color may be green light, and one of the light of the second color and the light of the third color may be red light and the other may be blue light. However, in other embodiments the light may have other wavelengths. For example, the light of the first color may be infrared light, the light of the second color may be visible light, and the light of the third color may be ultraviolet light.

Pixels 10 include first and second photoelectric conversion layers L1 and L2 stacked on each other in a direction in which the light impinges on pixel 10. First photoelectric conversion layer L1 generates a first electrical signal S1 in response to light incident on pixels 10. Also, second photoelectric conversion layer L2 is disposed under first photoelectric conversion layer L1 and generates a second electrical signal S2 in response to light transmitted through the first photoelectric conversion layer L1. Each of pixels 10 outputs not only one electrical signal, but at least two electrical signals, in response to light incident thereon. In general, the two electrical signals may be different from each other, having different amplitudes or values at any given time.

Digitization unit 20 generates first and second original data D1 and D2 by respectively digitizing the first and second electrical signals S1 and S2. Digitization unit 20 generates the first and second original data D1 and D2 respectively corresponding to the first and second electrical signals S1 and S2 by performing correlated double sampling (CDS) on each of the first and second electrical signals S1 and S2, comparing each of the first and second electrical signals S1 and S2, on which CDS is performed, to a ramp signal so as to generate comparator signals, and counting the comparator signals. First and second original data D1 and D2 may each be digital data having one of two discrete values, which may be referred to as “0” and “1” respectively. As first and second original data D1 and D2 are generated in response to light incident on a pixel, first and second original data D1 and D2 may be referred to as “image data.”

Correction unit 30 receives the first and second original data D1 and D2, and generates first and second corrected data C1 and C2 by using the first and second original data D1 and D2. The first corrected data C1 may have a value corresponding to the intensity of the light of the first color included in the light incident on pixels 10, and the second corrected data C2 may have a value corresponding to the intensity of the light of the second color included in the light incident on pixels 10.

If first photoelectric conversion layer L1 absorbed only the light of the first color included in the light incident on pixels 10, output the first electrical signal S1 corresponding to the light of the first color, and transmit the light of the second color and the light of the third color, and if second photoelectric conversion layer L2 absorbed only the light of the second color transmitted through first photoelectric conversion layer L1, and output the second electrical signal S2 corresponding to the light of the second color, then the first and second original data D1 and D2 would not need to be corrected. However, first photoelectric conversion layer L1 not only absorbs the light of the first color but absorbs some of the light of the second color and the light of the third color, and also transmits some of the light of the first color together with the light of the second color and the light of the third color. Consequently, the first electrical signal S1 output from first photoelectric conversion layer L1 includes not only a component corresponding to the light of the first color but also components corresponding to the light of the second color and the light of the third color. Also, the second electrical signal S2 output from second photoelectric conversion layer L2 includes not only a component corresponding to the light of the second color but also components corresponding to the light of the first color and the light of the third color. Correction unit 30 may generate the first corrected data C1 corresponding to the light of the first color and the second corrected data C2 corresponding to the light of the second color, by using the first and second original data D1 and D2 generated by digitizing the first and second electrical signals S1 and S2. Accordingly, color interference, generated when pixels 10 have a stacked structure may be reduced or eliminated.

Interpolation unit 40 may generate interpolation data C3 having a value corresponding to the intensity of the light of the third color. Interpolation unit 40 receives the first and second corrected data C1 and C2 of a pixel 10 and also receives corrected data of adjacent pixels 10. Interpolation unit 40 may generate the interpolation data C3 of pixel 10, which corresponds to the light of the third color, by using a color interpolation method based on data of adjacent pixels 10, which correspond to the light of the third color. Accordingly, pixel data of pixel 10 is generated. The pixel data includes the first and second corrected data C1 and C2, and the interpolation data C3.

Signal processing unit 50 may generate first through third color data C1 through C3 by performing image processing on the first and second corrected data C1 and C2, and the interpolation data C3 of pixels 10. Signal processing unit 50 performs color calibration in order to generate color data corresponding to actual colors of an object. For example, color correction for correcting color distortion due to lighting or brightness may be performed. In addition, signal processing unit 50 may perform color correction for reflecting a color setup of a user.

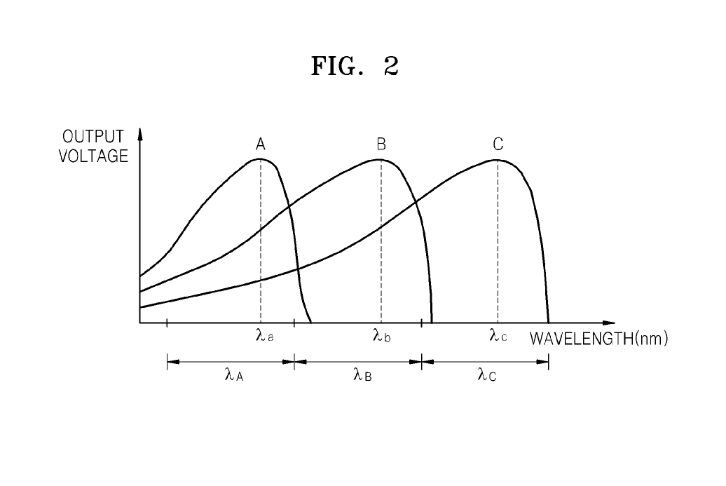

FIG. 2 is a graph exemplarily showing optical absorption characteristics of each photoelectric conversion layer in a pixel having a structure in which three photoelectric conversion layers are stacked on one another in a direction in which the light impinges on the pixel. It is assumed that the pixel includes a first photoelectric conversion layer A, a second photoelectric conversion layer B under the first photoelectric conversion layer A, and a third photoelectric conversion layer C under the second photoelectric conversion layer B.

Referring to FIG. 2, the first photoelectric conversion layer A has a maximum light absorption characteristic in a first wavelength range λ_{A} and, more particularly, at a first wavelength λₐ. Also, the second photoelectric conversion layer B has a maximum light absorption characteristic in a second wavelength range λ_{B} and, more particularly, at a second wavelength λ_{b}, and the third photoelectric conversion layer C has a maximum light absorption characteristic in a third wavelength range λ_{C} and, more particularly, at a third wavelength λ_{c}.

As illustrated in FIG. 2, light in the first wavelength range λ_{A} is also absorbed by the second and third photoelectric conversion layers B and C. Thus, electrical signals output from the second and third photoelectric conversion layers B and C include components of the light of the first wavelength range λ_{A} absorbed by the second and third photoelectric conversion layers B and C.

Also, light in the second wavelength range λ_{B} is absorbed not only by the second photoelectric conversion layer B but also by the first and third photoelectric conversion layers A and C. Thus, electrical signals output from the first and third photoelectric conversion layers A and C include components of the light of the second wavelength range λ_{B} absorbed by the first and third photoelectric conversion layers A and C. Light in the third wavelength range λ_{C} is absorbed not only by the third photoelectric conversion layer C but also by the second photoelectric conversion layer B. Thus, electrical signals output from the second photoelectric conversion layer B include a component of the light of the third wavelength range λ_{C} absorbed by the second photoelectric conversion layer B.

Accordingly, if it is assumed that an electrical signal output from the first photoelectric conversion layer A corresponds to the intensity of the light in the first wavelength range 4, that an electrical signal output from the second photoelectric conversion layer B corresponds to the intensity of the light in the second wavelength range λ_{B}, and that an electrical signal output from the third photoelectric conversion layer C corresponds to the intensity of the light in the third wavelength range λ_{C}, accurate color data may not be obtained. For example, when only red monochromatic light is incident on the pixel, the second and third photoelectric conversion layers B and C may also react to output electrical signals, and color data generated by digitizing them may not reproduce pure red and may reproduce red mixed with other colors. Accordingly, color interference due to light absorption characteristics of photoelectric conversion layers of a pixel should be reduced or eliminated. Correction unit 30 illustrated in FIG. 1 is used to reduce or eliminate the color interference.

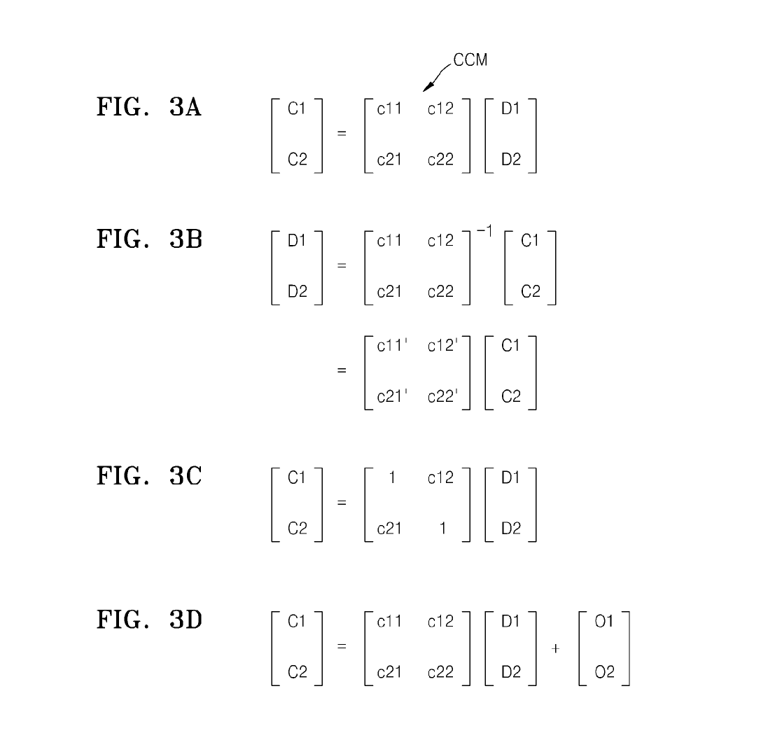

FIGS. 3A through 3D are diagrams for describing an example operation of an embodiment of correction unit 30 illustrated in FIG. 1.

Referring to FIG. 3A, the first and second corrected data C1 and C2 may be generated by multiplying the first and second original data D1 and D2 by a color correction matrix CCM. If one pixel has two photoelectric conversion layers, the color correction matrix CCM may be a 2×2 matrix. As illustrated in FIG. 3A, the color correction matrix CCM may have first through fourth coefficients c11, c12, c21, and c22.

The first corrected data C1 may be determined as a sum of: (1) a product of the first coefficient c11 and the first original data D1; and (2) a product of the second coefficient c12 and the second original data D2. Also, the second corrected data C2 may be determined as a sum of: (1) a product of the third coefficient c21 and the first original data D1; and (4) a product of the fourth coefficient c22 and the second original data D2.

FIG. 3B is a diagram for describing a method of calculating the first through fourth coefficients c11, c12, c21, and c22 of the color correction matrix CCM. The first and second original data D1 and D2 may be represented as a product of an inverse color correction matrix CCM⁻¹ and the first and second corrected data C1 and C2. The inverse color correction matrix CCM⁻¹ may be represented as first through fourth coefficients c11′, c12′, c21′, and c22′.

The first and second original data D1 and D2 have values obtained by quantizing the first and second electrical signals S1 and S2 output from the first and second photoelectric conversion layers L1 and L2. The first and second corrected data C1 and C2 have values corresponding to a component of light of a first color and a component of light of a second color, which are included in light incident on a pixel. Accordingly, if monochromatic light of the first color is incident on the pixel, the first corrected data C1 should have a value proportional to the intensity of the monochromatic light of the first color, and the second corrected data C2 should have a value 0. In this case, the first coefficient c11′ may be determined as a ratio of the value of the first original data D1 to the value of the first corrected data C1, i.e., D1/C1. Also, the third coefficient c21′ may be determined as a ratio of the value of the second original data D2 to the value of the first corrected data C1, i.e., D2/C1.

Otherwise, if monochromatic light of the second color is incident on the pixel, the second corrected data C2 should have a value proportional to the intensity of the monochromatic light of the second color, and the first corrected data C1 should have a value 0. In this case, the second coefficient c12′ may be determined as a ratio of the value of the first original data D1 to the value of the second corrected data C2, i.e., D1/C2. Also, the fourth coefficient c22′ may be determined as a ratio of the value of the second original data D2 to the value of the second corrected data C2, i.e., D2/C2.

As such, the first through fourth coefficients c11′, c12′, c21′, and c22′ of the inverse color correction matrix CCM⁻¹ may be determined. Accordingly, by inverting the inverse color correction matrix CCM⁻¹ μnce again, the first through fourth coefficients c11, c12, c21, and c22 of the color correction matrix CCM may be calculated.

Although an exemplary method of calculating the first through fourth coefficients c11, c12, c21, and c22 of the color correction matrix CCM is described above with reference to FIG. 3B, the first through fourth coefficients c11, c12, c21, and c22 of the color correction matrix CCM may be determined by another method. For example, the first through fourth coefficients c11, c12, c21, and c22 of the color correction matrix CCM may be set by a user. Also, the first through fourth coefficients c11, c12, c21, and c22 of the color correction matrix CCM may vary according to a location of a pixel in a pixel array, in order to reduce or eliminate a chromatic aberration effect of a lens.

FIG. 3C shows an example of the color correction matrix CCM. As illustrated in FIG. 3C, diagonal components of the color correction matrix CCM, i.e., the first and fourth coefficients c11 and c22, may be set as a value 1. In this case, the number of multipliers may be reduced by two. Although four multipliers and two adders are required to obtain the color correction matrix CCM illustrated in FIG. 3A, only two multipliers and two adders are required to obtain the color correction matrix CCM illustrated in FIG. 3C. The diagonal components of the color correction matrix CCM may be set as a value 1 because the signal processing unit 50 may perform color correction again. For example, since the signal processing unit 50 includes a digital gain block in order to perform a function such as white balance adjustment, a sum of coefficients in a row of the color correction matrix CCM of the correction unit 30 does not need to be fixed as a value 1.

Referring to FIG. 3D, the correction unit 30 may include an offset matrix for correcting offsets, in addition to the color correction matrix CCM. As illustrated in FIG. 3D, the first and second corrected data C1 and C2 may be generated by multiplying the first and second original data D1 and D2 by the color correction matrix CCM to calculate a product thereof, and then adding first and second offset data O1 and O2 to the product. The first and second offset data O1 and O2 are used to correct dark level current.

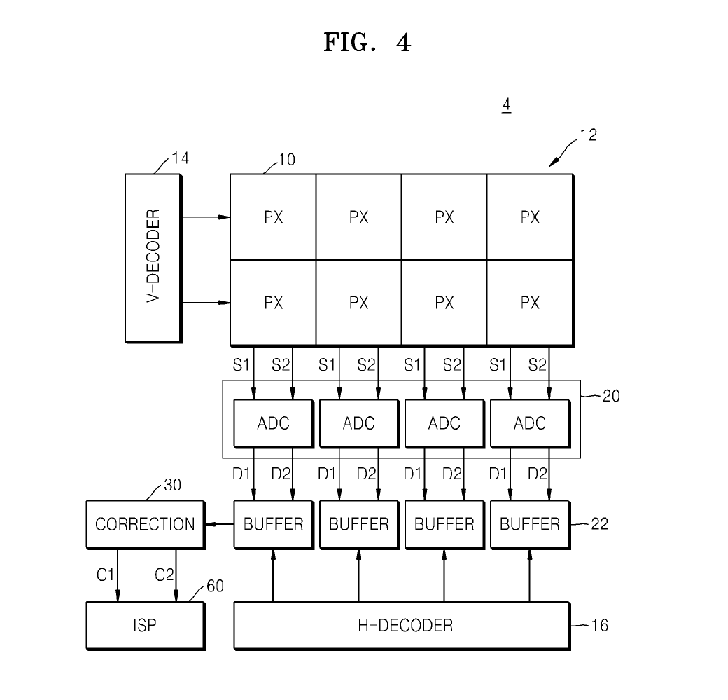

FIG. 4 is a block diagram of an image processing apparatus 4. Image processing apparatus 4 includes pixel array 12 comprising pixels 10, vertical (or row) decoder 14, horizontal (or column) decoder 16, digitization unit 20, buffers 22, correction unit 30, and image signal processor (JSP) 60.

Referring to FIG. 4, pixels 10 are aligned in an array of rows and columns in pixel array 12. Vertical decoder 14 and horizontal decoder 16 may select a pixel 10 corresponding to an address from pixel array 12. In response to a row address, vertical decoder 14, which may be referred to as a row decoder, activates a row of pixel array 12 corresponding to the row address. In response to a column address, horizontal decoder 16, which may be referred to as a column decoder, activates a column of pixel array 12 corresponding to the column address.

Pixels 10 of pixel array 12 obtain an image of an object, which may be incident through an optical lens, and then are activated in a raster scan method. That is, pixels 10 in a first row of pixel array 12 sequentially output the first and second electrical signals S1 and S2. After that, pixels 10 in a second row sequentially output the first and second electrical signals S1 and S2. In this manner, all pixels 10 in the remaining rows sequentially output the first and second electrical signals S1 and S2. For this, vertical decoder 14 sequentially activates pixel array 12 from the first row to the last row. Horizontal decoder 16 sequentially activates all columns of pixel array 12 while vertical decoder 14 activates one row of the pixels 10. As such, pixels 10 of pixel array 12 output the first and second electrical signals S1 and S2 in a raster scan method.

Digitization unit 20 includes analog-digital converters (ADCs) for converting the first and second electrical signals S1 and S2 output from pixels 10 of each column into the first and second original data D1 and D2 that are digital data. The first and second original data D1 and D2 output from the ADCs are temporarily stored in buffers 22. Horizontal decoder 16 may control buffers 22 in such a way that the first and second original data D1 and D2 stored in buffers 22 are sequentially output. For example, the first and second original data D1 and D2 stored in leftmost buffer 22 may be output, and then the first and second original data D1 and D2 stored in second leftmost buffer 22 may be output, etc. In this manner, the first and second original data D1 and D2 of one row of pixels 10 may be sequentially output. The above-described operation of sequentially outputting the first and second original data D1 and D2 of pixels 10 by using buffers 22 may be referred to as serialization.

Correction unit 30 may receive the sequentially output first and second original data D1 and D2, and may sequentially generate the first and second corrected data C1 and C2 by using the above-described color correction matrix. The generated first and second corrected data C1 and C2 are output to ISP 60. ISP 60 may collect the first and second corrected data C1 and C2 of all pixels 10. ISP 60 may generate interpolation data of all pixels 10 by using a color interpolation method. Consequently, the first and second corrected data C1 and C2, and interpolation data of each of the pixels 10, are generated. The first and second corrected data C1 and C2 and the interpolation data may correspond to three color data of pixels 10. For example, if the first and second corrected data C1 and C2 are green and blue data, the interpolation data may be red data.

ISP 60 may perform various types of color correction such as white balance adjustment and contrast adjustment.

Typically, pixel array 12, vertical decoder 14, horizontal decoder 16, digitization unit 20, and buffers 22 may be included in an image sensor. Correction unit 30 may be disposed at a rear end of buffers 22 and may be included in the image sensor. In this case, the image sensor outputs the first and second corrected data C1 and C2 of pixels 10.

Alternatively, correction unit 30 may be included in ISP 60. In this case, the image sensor may output the first and second original data D1 and D2, and ISP 60 may receive the first and second original data D1 and D2, may generate the first and second corrected data C1 and C2, and may perform various types of image signal processing such as interpolation and color correction on the generated first and second corrected data C1 and C2.

According to the image apparatus illustrated in FIG. 4, the first and second electrical signals S1 and S2 output from pixels 10 are converted by the ADCs of the digitization unit 20 into the first and second original data D1 and D2. The first and second original data D1 and D2 are temporarily stored in buffers 22 and then are sequentially output under the control of horizontal decoder 16. That is, the first and second original data D1 and D2 are serialized according to locations of pixels 10 by using a raster scan method. Correction unit 30 receives the serialized first and second original data D1 and D2, and corrects and converts them into the first and second corrected data C1 and C2. ISP 60 performs image signal processing on the first and second corrected data C1 and C2.

According to another embodiment, after serialization, in order to compensate for non-uniform electrical characteristics of pixels 10, sensor compensation may be performed. For example, although light having the same intensity is incident, different ones of pixels 10 may react to different levels and thus may output electrical signals having differing magnitudes or other characteristics. In order to reduce or eliminate the above non-uniformity, sensor compensation may be performed. Sensor compensation may be performed simultaneously with correction performed by correction unit 30. Also, sensor compensation may be performed after correction performed by correction unit 30.

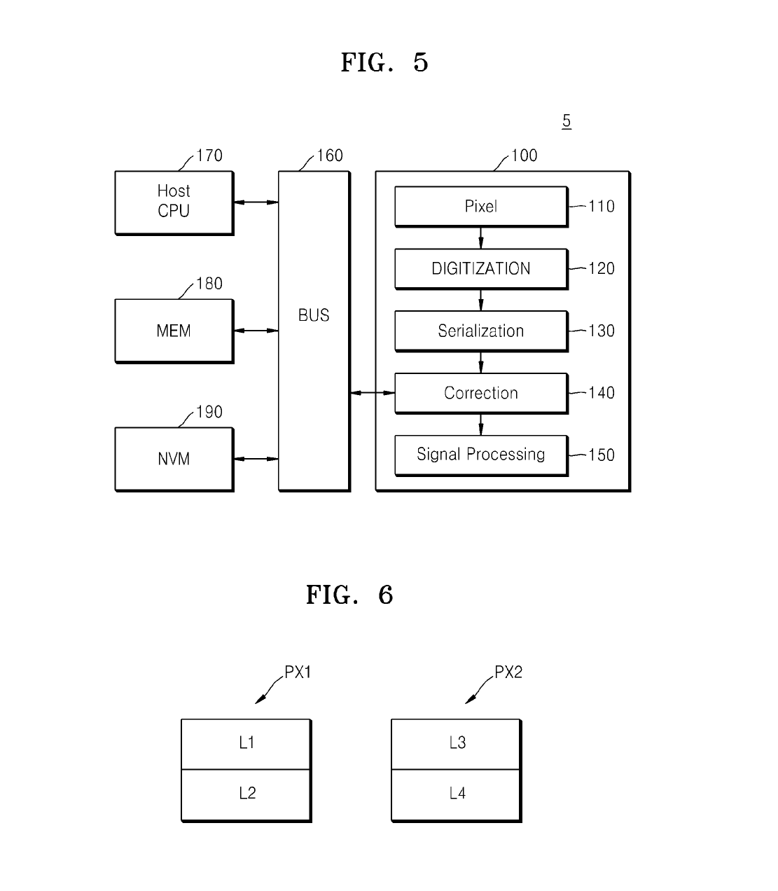

FIG. 5 is a block diagram of a system 5 including an image processing apparatus 100.

Referring to FIG. 5, the image apparatus 100 may include pixels 110, a digitization unit 120, a serialization unit 130, a correction unit 140, and a signal processing unit 150. Pixels 110 are substantially the same as pixels 10 illustrated in FIG. 1. Pixels 110 are aligned in a matrix to form a pixel array. Pixels 110 each include first and second photoelectric conversion layers L1 and L2. First photoelectric conversion layer L1 generates the first electrical signal S1 by using light incident on pixels 110. Also, second photoelectric conversion layer L2 is disposed under first photoelectric conversion layer L1, and generates the second electrical signal S2 by using light transmitted through first photoelectric conversion layer L1. Pixels 110 each output not only one electrical signal, but at least two electrical signals.

Digitization unit 120 is substantially the same as digitization unit 20 illustrated in FIG. 1. Digitization unit 120 converts the first and second electrical signals S1 and S2 output from pixels 110 into the first and second original data D1 and D2, respectively.

Serialization unit 130 may include buffers 22, and horizontal decoder 16 illustrated in FIG. 4 and, as described above, sequentially outputs the first and second original data D1 and D2 of pixels 110 in pixel array 12.

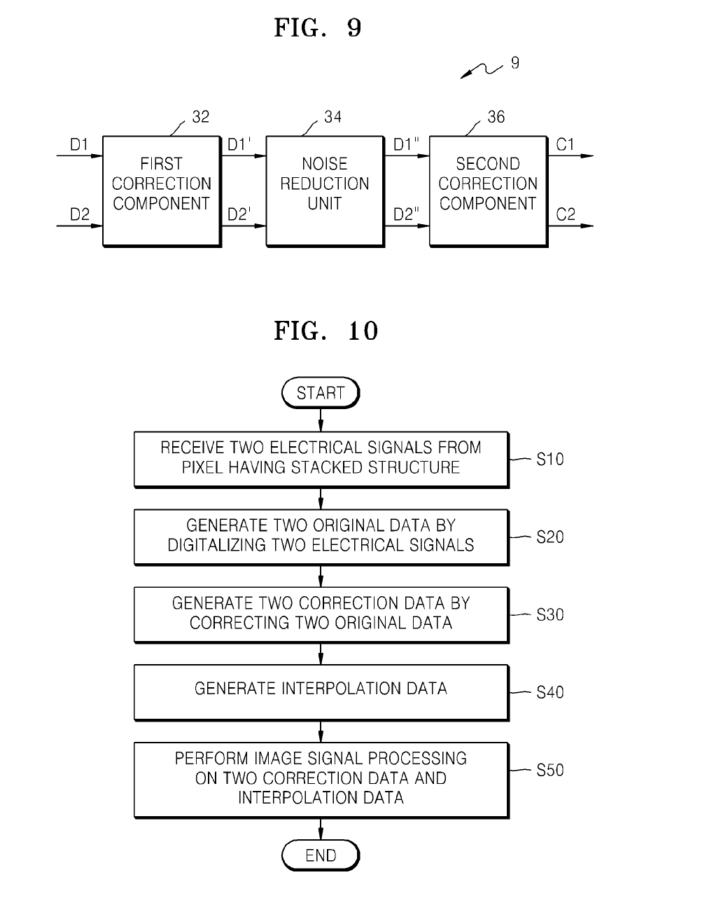

Correction unit 140 may be substantially the same as correction unit 30 illustrated in FIG. 1, or correction unit 9 described in detail with respect to FIG. 9, below. Correction unit 140 generates the first and second corrected data C1 and C2 by correcting the sequentially output first and second original data D1 and D2. Correction unit 140 may convert the first and second original data D1 and D2 into the first and second corrected data C1 and C2 by using a color correction matrix. As described above, the color correction matrix may include coefficients, and characteristics of the color correction matrix and characteristics of correction unit 140 may vary according to values of the coefficients.

Signal processing unit 150 may perform various types of image signal processing on the color-corrected first and second corrected data C1 and C2, such as additional color correction, white balance adjustment, noise reduction, and/or brightness adjustment.

Image apparatus 100 may be connected to a data bus 160. Image apparatus 100 may be controlled by a host central processing unit (CPU) 170 connectable to data bus 160. Also, data bus 160 may be connected to a memory 180 and a non-volatile memory 190.

Memory 180 may store image data obtained by image apparatus 100. Non-volatile memory 190 may store the coefficients of the color correction matrix via host CPU 170. A user may change the coefficients via host CPU 170. Also, the coefficients for different pixels 110 may have different values according to the locations of the pixels 110 in the pixel array. In more detail, if the pixel 110 is located at a center part of the pixel array, the color correction matrix may include a first set of coefficients. Otherwise, if the pixel 110 is located at an edge part of the pixel array, the color correction matrix may include a second set of coefficients. Consequently, the system may obtain a more natural, sharp, and high-quality image.

FIG. 6 is a cross-sectional diagram of example embodiments of pixels of an image processing apparatus.

Referring to FIG. 6, the pixels of the image processing apparatus may include two types of pixels, e.g., first pixels PX1 and second pixels PX2.

First pixels PX1 and second pixels PX2 may be substantially the same as pixels 10 illustrated in FIG. 1. First pixels PX1 include first and second photoelectric conversion layers L1 and L2 stacked on one another in a direction in which the light L impinges on pixel PX1. First photoelectric conversion layer L1 generates a first electrical signal by using light incident on the first pixels PX1. Also, second photoelectric conversion layer L2 is disposed under first photoelectric conversion layer L1, and generates a second electrical signal by using light transmitted through first photoelectric conversion layer L1. That is, first pixels PX1 each may output the first and second electrical signals which in general are different from each other at any given point in time.

Second pixels PX2 include third and fourth photoelectric conversion layers L3 and L4 stacked on each other in a direction in which the light L impinges on pixel PX2. Third photoelectric conversion layer L3 generates a third electrical signal by using light incident on second pixels PX2. Also, fourth photoelectric conversion layer L4 is disposed under third photoelectric conversion layer L3, and generates a fourth electrical signal by using light transmitted through the third photoelectric conversion layer L3. That is, second pixels PX2 each may output the third and fourth electrical signals.

Digitization unit 20 illustrated in FIG. 1 receives the first and second electrical signals output from first pixels PX1 and the third and fourth electrical signals output from second pixels PX2, and generates first through fourth original data by respectively digitizing the first through fourth electrical signals.

Also, correction unit 30 illustrated in FIG. 1 may generate first corrected data corresponding to light of a first color and second corrected data corresponding to light of a second color, by using the first and second original data. Also, correction unit 30 may generate third corrected data corresponding to light of a third color and fourth corrected data corresponding to light of a fourth color, by using the third and fourth original data. Here, the first and third colors may be the same color, for example, green. Also, the second color may be red and the fourth color may be blue. Alternatively, the first color may be blue, the third color may be red, and the second and fourth colors may be green.

Interpolation unit 40 illustrated in FIG. 1 may generate first interpolation data of first pixel PX1, which corresponds to the light of the third color, by using the fourth corrected data of second pixels PX2 adjacent to the first pixel PX1. Also, interpolation unit 40 may generate second interpolation data of second pixel PX2, which corresponds to the light of the second color, by using the second corrected data of first pixels PX1 adjacent to second pixel PX2.

For example, it is assumed that the first and second corrected data are green and red data generated by first pixels PX1, and that the third and fourth corrected data are green and blue data generated by second pixels PX2. Interpolation unit 40 generates the blue data of the first pixel PX1 by using the blue data of second pixels PX2 adjacent to first pixel PX1. Likewise, interpolation unit 40 generates the red data of second pixel PX2 by using the red data of first pixels PX1 adjacent to second pixel PX2. Consequently, the red, green, and blue data of the first pixels PX1 are generated, and the red, green, and blue data of second pixels PX2 are generated.

First and third photoelectric conversion layers L1 and L3 may output electrical signals by mainly reacting with light of the same color. For example, first and third photoelectric conversion layers L1 and L3 may mainly react with green light. Second and fourth photoelectric conversion layers L2 and L4 may output electrical signals by mainly reacting with light of different colors. For example, second photoelectric conversion layer L2 may mainly react with red light, and fourth photoelectric conversion layer L4 may mainly react with blue light.

Alternatively, second and fourth photoelectric conversion layers L2 and L4 may mainly react with light of the same color, and first and third photoelectric conversion layers L1 and L3 may mainly react with light of different colors. For example, first photoelectric conversion layer L1 may mainly react with red light, third photoelectric conversion layer L3 may mainly react with blue light, and second and fourth photoelectric conversion layers L2 and L4 may mainly react with green light.

First and second pixels PX1 and PX2 may form a pixel array and may be alternately aligned in the pixel array.

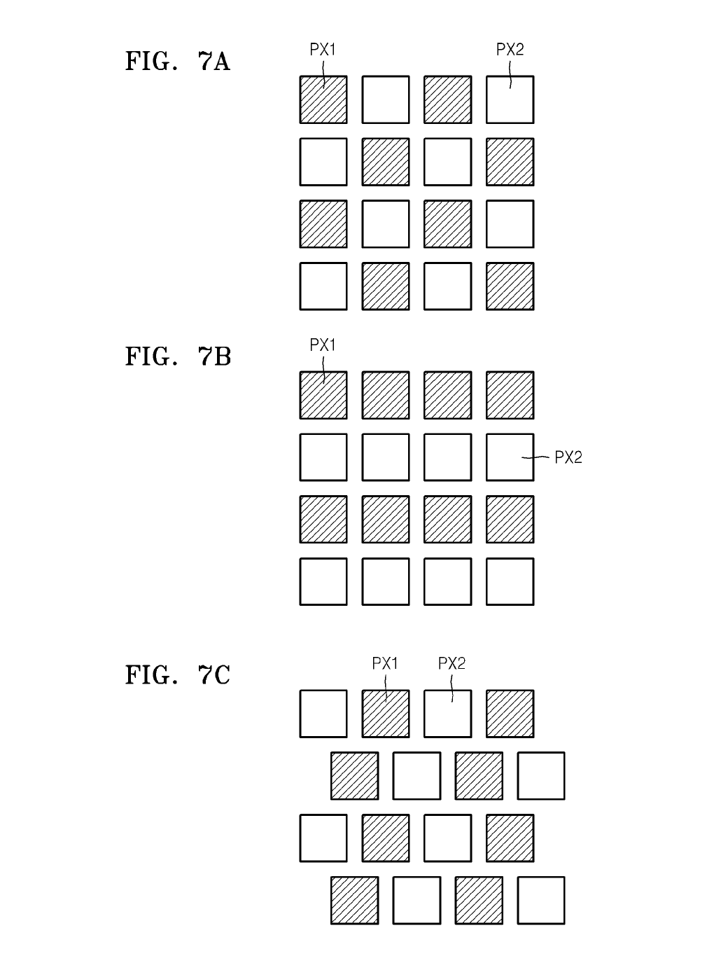

FIGS. 7A through 7C are diagrams showing example alignments of pixels of an image processing apparatus, according to example embodiments of the inventive concept.

Referring to FIGS. 7A through 7C, a plurality of first pixels PX1 and a plurality of second pixels PX2 form a pixel array.

As illustrated in FIG. 7A, first and second pixels PX1 and PX2 may be alternately aligned in both the horizontal direction (e.g., along a row) and the vertical direction (e.g., along a column).

Also, as illustrated in FIG. 7B, first and second pixels PX1 and PX2 may be alternately aligned in either the horizontal direction (e.g., along a row) or the vertical direction (e.g., along a column).

Otherwise, as illustrated in FIG. 7C, first and second pixels PX1 and PX2 may be alternately aligned in either the horizontal and vertical directions, and may be aligned in zigzags in the other of the horizontal and vertical directions. For example, if first and second pixels PX1 and PX2 are alternately aligned in the horizontal direction (e.g., along a row), pixels in even-number rows and pixels in odd-number rows may have an offset therebetween in the horizontal direction. In some embodiments, the size of the offset may be a half of a pitch of one pixel in the horizontal direction. In that case, it may be seen that the columns are not linearly structured, but instead zigzag sideways as they proceed from one end to the other thereof.

In addition to the alignments shown in FIGS. 7A through 7C, the first and second pixels PX1 and PX2 may have various other alignments.

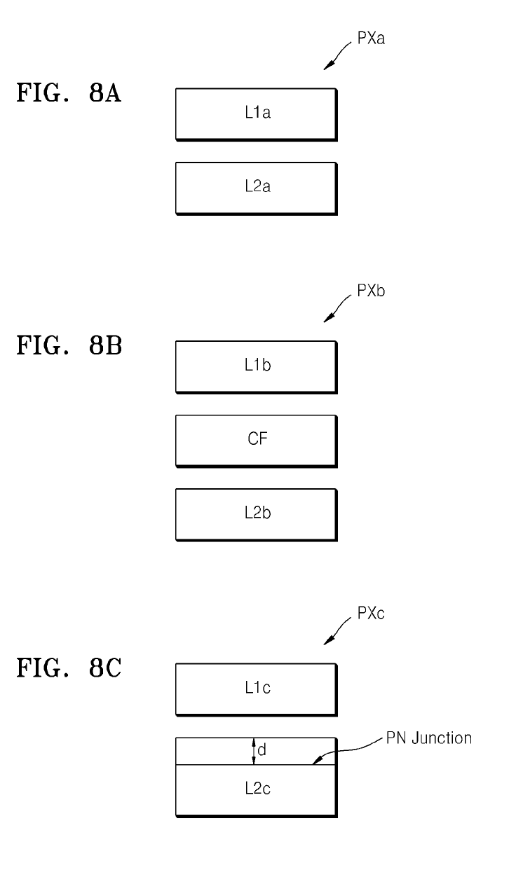

FIGS. 8A through 8C are cross-sectional diagrams of some embodiments of pixels of an image processing apparatus.

Referring to FIG. 8A, a first pixel PXa having a stacked structure is illustrated. A first photoelectric conversion layer L1a of first pixel PXa includes an organic material for absorbing light of a first color more than light of a second color and light of a third color. That is, the organic material of first photoelectric conversion layer L1a has a maximum absorption spectrum in a wavelength range of the light of the first color. Although it is intended that the organic material of first photoelectric conversion layer L1a transmit all of the light of the second color and the light of the third color without absorbing them, in actuality, some of the light of the second color and the light of the third color may be absorbed. Also, although it is intended that the organic material of first photoelectric conversion layer L1a absorbs all of the light of the first color, in actuality, all of the light of the first color may not be absorbed and some of it may be transmitted.

A second photoelectric conversion layer L2a of first pixel PXa may include an organic material for absorbing the light of the second color more than the light of the first color and the light of the third color. That is, the organic material of second photoelectric conversion layer L2a has a maximum absorption spectrum in a wavelength range of the light of the second color. Although it is intended that the organic material of second photoelectric conversion layer L2a absorbs only the light of the second color, actually, the organic material of second photoelectric conversion layer L2a may also absorb some of the light of the first color or the light of the third color.

In more detail, each of first and second photoelectric conversion layers L1a and L2a includes first and second electrodes, and an organic material layer between the first and second electrodes. The first and second electrodes may be formed of a transparent conductive material. The organic material layer is formed of a different organic material according to mostly absorbed wavelengths of light. It is assumed that light is incident on the first electrode of each of first and second photoelectric conversion layers L1a and L2a.

A work function of the first electrode has a value greater than that of a work function of the second electrode. The first and second electrodes may be transparent oxide electrodes formed of at least one oxide selected from the group consisting of indium-doped tin oxide (ITO), indium-doped zinc oxide (IZO), zinc oxide (ZnO), tin dioxide (SnO₂), antimony-doped tin oxide (ATO), aluminum-doped zinc oxide (AZO), gallium-doped zinc oxide (GZO), titanium dioxide (TiO₂), and fluorine-doped tin oxide (FTO). Also, the second electrode may be a metal thin film formed of at least one metal selected from the group consisting of aluminum (Al), copper (Cu), titanium (Ti), gold (Au), platinum (Pt), silver (Ag), and chromium (Cr). If the second electrode is formed of metal, in order to achieve transparency, it may be formed to a thickness equal to or less than 20 nm.

The organic material layer includes P-type and N-type organic material layers having a PN junction structure. The P-type organic material layer is formed to contact the first electrode, and the N-type organic material layer is formed between and to contact the P-type organic material layer and the second electrode.

The P-type organic material layer may be formed of a semiconductor material having holes functioning as a plurality of carriers, and is not particularly limited to any material as long as the material absorbs a desired wavelength band of light. The N-type organic material layer may be formed of an organic semiconductor material having electrons functioning as a plurality of carriers, for example, fullerene carbon (C₆₀).

At least one of the P-type and N-type organic material layers may be formed of an organic material for causing photoelectric conversion by selectively absorbing only a desired wavelength band of light. In order to cause photoelectric conversion by transmitting only light of a desired color and selectively absorbing wavelength bands of light other than a wavelength band of the transmitted light, red, green, and blue photoelectric conversion layers may be formed of different organic materials.

For example, the blue photoelectric conversion layer may include a P-type organic material layer deposited with N,N′-Bis(3-methylphenyl)-N,N′-bis(phenyl)benzidine (TPD) for causing photoelectric conversion by absorbing only blue light, and an N-type organic material layer deposited with C₆₀. In this structure, due to light incident on a light-receiving surface, the P-type organic material layer generates excitons and may selectively absorb a desired wavelength of light.

As another example, at least one of P-type and N-type organic material layers of a photoelectric conversion layer may be formed of a material for selectively absorbing wavelengths of an infrared region. The material for selectively absorbing infrared light may be an organic material such as an organic pigment, for example, a phthalocyanine-based material, a naphthoquinone-based material, a naphthalocyanine-based material, a pyrrole-based material, a polymer-condensed-azo-based material, an organic-metal-complex-based material, an anthraquinone-based material, a cyanine-based material, a mixture thereof, or a compound thereof. Also, an inorganic material such as an antimony-based material may be mixed thereto, and nano particles may be used to achieve transparency.

As another example, a first P-type organic material layer, an exciton blocking layer, a second P-type organic material layer, and an N-type organic material layer may be formed between the first and second electrodes.

In this case, the first P-type organic material layer may be formed close to a light-receiving surface, and may be formed of a combination of light-absorbing organic materials for transmitting a wavelength band of a desired color in a visible light region and for selectively absorbing wavelength bands of light other than the wavelength band of the desired color. The second P-type organic material layer may be formed under the first P-type organic material layer, and may be formed of a light-absorbing organic material for absorbing a desired wavelength. The N-type organic material layer may be formed under the second P-type organic material layer, may cause photoelectric conversion by using a PN junction structure, and may convert light of a desired color to current.

Also, in order to suppress excitons formed in the first P-type organic material layer from moving toward the second P-type organic material layer, the exciton blocking layer for blocking movement of excitons may be formed between the first and second P-type organic material layers. If the exciton blocking layer is formed to have bandgap energy greater than that of the first P-type organic material layer, energy of the excitons generated in the first P-type organic material layer is less than the bandgap energy of the exciton blocking layer, and the electrons may not move. For example, from among oligothiophene-based derivatives, phenyl hexa thiophene (P6T) has bandgap energy of about 2.1 eV, is able to selectively absorb blue light wavelengths of 400 to 500 nm, and thus may be effectively used to form the first P-type organic material layer for a red color. From among oligothiophene-based derivatives, bi-phenyl-tri-thiophene (BP3T) is able to effectively block blue light wavelengths of 400 to 550 nm, has bandgap energy of about 2.3 eV, which is greater than that of P6T by about 0.2 eV, and thus may be effectively used as the exciton blocking layer for a red color.

The second P-type organic material layer may be formed of a light-absorbing organic material for absorbing all wavelengths of visible light, for example, a phthalocyanine derivative such as copper phthalocyanine (CuPc).

As another example, a P-type organic material layer, an intrinsic layer, and an N-type organic material layer may be formed between the first and second electrodes. The intrinsic layer codeposits a P-type organic material and an N-type organic material between the P-type and N-type organic material layers. For example, in a green pixel, a P-type organic material layer formed of TPD, an intrinsic layer on which TPD and N,N′-dimethyl-3,4,9,10-perylenedicarboximide (Me-PTC) are codeposited, and an N-type organic material layer formed of naphthalene tetracarboxylic anhydride (NTCDA) may be formed between the first and second electrodes.

As another example, a first buffer layer may be formed between the first electrode and the P-type organic material layer. The first buffer layer may be formed of a P-type organic semiconductor material, and may block electrons. Also, a second buffer layer may be formed between the second electrode and the N-type organic material layer. The second buffer layer may be formed of an N-type organic semiconductor material, and may block holes.

In more detail, the first buffer layer may be formed of, but not limited to, polyethylene dioxythiophene (PEDOT)/polystyrene sulfonate (PSS). Also, the second buffer layer may be formed of, but is not limited to, 2,9-dimethyl-4,7-diphenyl-1,10-phenanthroline (BCP), lithium fluoride (LiF), copper phthalocyanine, polythiophene, polyaniline, polyacetylene, polypyrrole, polyphenylenevinylene, or a derivative thereof.

Referring to FIG. 8B, a second pixel PXb having a stacked structure is illustrated. A first photoelectric conversion layer L1b of second pixel PXb includes an organic material for absorbing light of a first color more than light of a second color and light of a third color. That is, the organic material of first photoelectric conversion layer L1b has a maximum absorption spectrum in a wavelength range of the light of the first color. First photoelectric conversion layer L1b including the organic material is substantially the same as one of first and second photoelectric conversion layers L1a and L2a illustrated in FIG. 8A, and thus a detailed description thereof is not repeatedly provided here.

Second pixel PXb further includes a color filter CF and a second photoelectric conversion layer L2b under the first photoelectric conversion layer L1b. The color filter CF may transmit only light of a certain wavelength band and may block light of the other wavelength bands. For example, color filter CF may transmit at least one of red light, green light, blue light, infrared light, and ultraviolet light, and may block the others. In the current embodiment, color filter CF disposed between first and second photoelectric conversion layers L1b and L2b may transmit only the light of the second color (e.g., green), and may block the light of the first color (e.g., red) and the light of the third color (e.g., blue).

Second photoelectric conversion layer L2b may include a photo diode formed in a semiconductor substrate. The photo diode may be formed, for example, by injecting second conductive-type ions into a first conductive-type semiconductor substrate. For example, the photo diode may be formed by injecting n-type ions into a p-type semiconductor substrate. The photo diode absorbs light transmitted through color filter CF and filtered to a certain wavelength band, and emits charges.

Also, as another example, second photoelectric conversion layer L2b may include an N-type photo diode (NPD), and a P-type pinned photo diode (PPD) on the NPD, which are formed in a semiconductor substrate. The NPD may accumulate charges generated due to incident light, and the P-type PPD may reduce dark level current by reducing electron-hole pairs (EHPs) thermally generated in the semiconductor substrate. Also, a region of the semiconductor substrate under the NPD may be used as a photoelectric conversion region. A maximum impurity density of the NPD may be 1×10¹⁵ to 1×10¹⁸ atoms/cm³, and an impurity density of the P-type PPD may be 1×10¹⁷ to 1×10²° atoms/cm³. However, the doping densities and locations may vary according to a manufacturing process and design, and thus the maximum impurity density of the NPD and the impurity density of the P-type PPD are not limited thereto.

Referring to FIG. 8C, a third pixel PXc having a stacked structure is illustrated. A first photoelectric conversion layer L1c of third pixel PXc includes an organic material for absorbing light of a first color more than light of a second color and light of a third color. That is, the organic material of first photoelectric conversion layer L1c has a maximum absorption spectrum in a wavelength range of the light of the first color. First photoelectric conversion layer L1c including the organic material is substantially the same as one of first and second photoelectric conversion layers L1a and L2a illustrated in FIG. 8A, and thus a detailed description thereof is not repeatedly provided here.

Third pixel PXc includes a second photoelectric conversion layer L2c under the first photoelectric conversion layer L1c. The second photoelectric conversion layer L2c includes a PN junction structure formed in a semiconductor substrate. Unlike the second pixel PXb, the third pixel PXc does not include a color filter. However, in the second photoelectric conversion layer L2c, a distance d from a surface of the semiconductor substrate to the PN junction structure may vary according to a color of light on which photoelectric conversion is to be performed. For example, if the second photoelectric conversion layer L2c is to react with blue light, the distance d is determined in consideration of a depth to which the blue light is absorbed into the semiconductor substrate. Also, if the second photoelectric conversion layer L2c is to react with red light, the distance d is determined in consideration of a depth to which the red light is absorbed into the semiconductor substrate. In general, if a wavelength of light is long, a depth to which the light is absorbed into the semiconductor substrate is large. Accordingly, a depth of a PN junction structure of a photoelectric conversion layer reacting with red light is greater than that of a PN junction structure of a photoelectric conversion layer reacting with blue light. For example, a depth of a PN junction structure of a photoelectric conversion layer reacting with blue light may be about 0.2 μm. A depth of a PN junction structure of a photoelectric conversion layer reacting with green light may be about 0.6 μm. A depth of a PN junction structure of a photoelectric conversion layer reacting with red light may be about 2.0 μm.

FIG. 9 is a block diagram of an embodiment of correction unit 9 of an image processing apparatus. Correction unit 9 may be an embodiment of correction unit 30 in FIGS. 1 and 4, and/or correction unit 140 shown in FIG. 5.

Referring to FIG. 9, correction unit 9 may include a first correction component 32, a noise reduction unit 34, and a second correction component 36.

Each of the first and second correction components 32 and 36 may use the color correction matrix CCM illustrated in FIGS. 3A through 3D and described above. First correction unit 32 may generate first and second temporary data D1′ and D2′ by performing primary correction on the first and second original data D1 and D2 by using a first color correction matrix CCM1. Diagonal components of the first color correction matrix CCM1 may have values equal to or greater than 1 and equal to or less than 1.5, and absolute values of non-diagonal components of the first color correction matrix CCM1 may be equal to or less than 0.8.

Noise reduction unit 34 may perform noise reduction on the first and second temporary data D1′ and D2′. For noise reduction, a low pass filter may be used. First and second noise-reduced temporary data D1″ and D2″ may be generated.

Second correction unit 36 may generate the first and second corrected data C1 and C2 by performing secondary corrected on the first and second noise-reduced or noise-filtered temporary data D1″ and D2″ by using a second color correction matrix CCM2.

Correction unit 9 illustrated in FIG. 9 performs color correction twice. If color correction is performed once, absolute values of coefficients of a color correction matrix may be increased to be equal to or greater than 2. This means that noise may be amplified. Accordingly, it is beneficial that coefficients of the first color correction matrix CCM1 used to perform primary color correction not have values greater than 1.5.

After that, in order to perform low pass filtering for noise reduction, data of a pixel to be filtered and adjacent pixels of the pixel may be required. For example, in FIG. 4, instead of performing noise reduction on original data sequentially output from buffers 22, original data of all pixels 10 may be stored in a storage unit and then noise reduction may be performed on all pixels 10. In some embodiments, noise reduction unit 34 may be included in ISP 60 illustrated in FIG. 4.

Second correction component 36 may perform secondary color correction on the noise-reduced or noise-filtered data. In some embodiments, second correction unit 36 may be included in ISP 60 illustrated in FIG. 4.

FIG. 10 is a flowchart of an image processing method.

Referring to FIG. 10, two electrical signals are received from pixels having a stacked structure (S 10). An image sensor includes an array of the pixels. According to the current embodiment, the pixels have a stacked structure in which two photoelectric conversion layers are stacked on one another. Each of the two photoelectric conversion layers outputs an electrical signal corresponding to the intensity of received light.

Two original data are generated by digitizing the two electrical signals (S20). The two original data are generated by individually digitizing the two electrical signals output from each pixel. For example, first original data is generated by using a first electrical signal, and is not influenced by a second electrical signal. Likewise, second original data is generated by digitizing the second electrical signal, and is not influenced by the first electrical signal.

Two corrected data are generated by correcting the two original data (S30). The two corrected data are generated by performing color correction on the two original data generated in operation S20. In operation S30, the color correction matrix CCM illustrated in FIGS. 3A through 3D may be used. For example, first corrected data may be generated by using the second original data as well as the first original data. Second corrected data also may be generated by using the first and second original data. As described above, the original data are converted into the corrected data in order to reduce or eliminate color interference due to the stacked structure of the pixels. Although a first photoelectric conversion layer should output a first electrical signal corresponding to light of a first color, since an organic material reacting with the light of the first color is used instead of using a color filter in front of the first photoelectric conversion layer, components of light of a second color and light of a third color may also be converted into the first electrical signal. Such color interference occurs at a certain ratio according to structural parameters of the pixel. In operation S30, the color interference may be reduced by using a color correction matrix.

Operation S30 may include primary color correction, noise reduction, and secondary color correction according to the embodiment illustrated in FIG. 9. Primary color correction may be performed on the two original data by using a first color correction matrix. Consequently, two temporary data may be generated. Low pass filtering for noise reduction may be performed on the two temporary data. Then, secondary color correction may be performed on the two noise-reduced temporary data by using a second color correction matrix.

In addition to the two corrected data, interpolation data is generated (S40). The interpolation data may be generated by using a color interpolation method. Although two color data, i.e., the two corrected data, are generated for each pixel after operation S30, in a typical application three color data are required for each pixel. Accordingly, the other (third) color data is generated by using color data of adjacent pixels in operation S40. After operation S40, three color data, i.e., the two corrected data and the interpolation data, are generated for each pixel.

Image signal processing is performed on the two corrected data and the interpolation data (S50). In operation S50, hue correction, brightness correction, saturation correction, white balance adjustment, correction of color shift due to lighting, etc. may be performed. For image signal processing, the two corrected data and the interpolation data may be stored in a storage unit of an ISP.

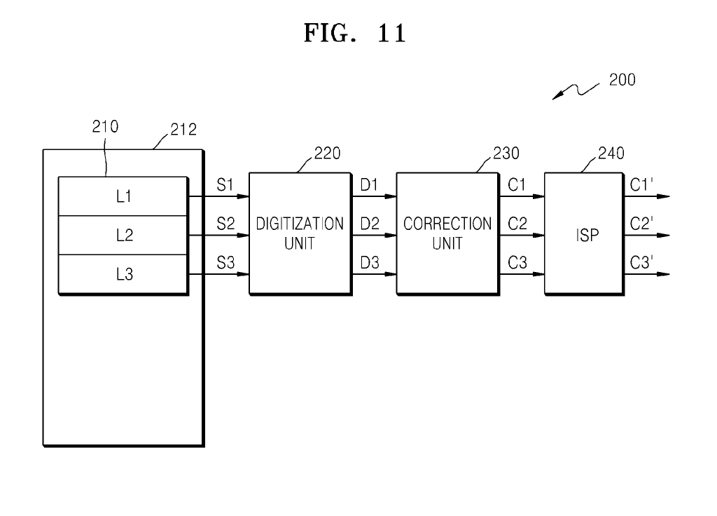

FIG. 11 is a block diagram of an image apparatus 200.

Referring to FIG. 11, the image apparatus 200 includes pixels 210, a digitization unit 220, and a correction unit 230. As illustrated in FIG. 11, image apparatus 200 may further include an ISP 240.

Image apparatus 200 may include a pixel array 212 including pixels 210 aligned in rows and columns Pixel array 212 may include pixels 210 having a triple-layer stacked structure as illustrated in FIG. 11.

Light incident on pixels 210 may be converted through an optical lens into electrical signals that are then output. For example, light may include infrared light, visible light, and ultraviolet light. In the description to follow, it is assumed that the light includes light of a first color, light of a second color, and light of a third color. For example, the light of the first color may be green light, and one of the light of the second color and the light of the third color may be red light, and the other may be blue light. As another example, the light of the first color may be infrared light, the light of the second color may be visible light, and the light of the third color may be ultraviolet light. However, the inventive concept is not limited thereto.

Each of the pixels 210 include first through third photoelectric conversion layers L1 through L3 stacked on each other in a direction in which the light impinges on the pixel 210. First photoelectric conversion layer L1 generates a first electrical signal S1 by using light incident on pixels 210. Second photoelectric conversion layer L2 is disposed under first photoelectric conversion layer L1, and generates a second electrical signal S2 by using light transmitted through first photoelectric conversion layer L1. Third photoelectric conversion layer L3 is disposed under second photoelectric conversion layer L2, and generates a third electrical signal S3 by using light transmitted through first and second photoelectric conversion layers L1 and L2. Each of pixels 210 outputs three electrical signals.

Digitization unit 220 generates first through third original data D1 through D3 by respectively digitizing the first through third electrical signals S1 through S3. The digitization unit 220 generates the first through third original data D1 through D3 respectively corresponding to the first through third electrical signals S1 through S3 by performing CDS on each of the first through third electrical signals S1 through S3, comparing each of the first through third electrical signals S1 through S3, on which CDS is performed, to a ramp signal so as to generate first through third comparator signals, and counting the first through third comparator signals.

Correction unit 230 receives the first through third original data D1 through D3, and generates first through third corrected data C1 through C3 by using the first through third original data D1 through D3. The first corrected data C1 may have a value corresponding to the intensity of the light of the first color included in the light incident on pixels 210, the second corrected data C2 may have a value corresponding to the intensity of the light of the second color included in the light incident on pixels 210, and the third corrected data C3 may have a value corresponding to the intensity of the light of the third color included in the light incident on pixels 210.

The first electrical signal S1 output from first photoelectric conversion layer L1 includes not only a component corresponding to the light of the first color but also components corresponding to the light of the second color and the light of the third color. Also, the second electrical signal S2 output from the second photoelectric conversion layer L2 includes not only a component corresponding to the light of the second color but also components corresponding to the light of the first color and the light of the third color. Furthermore, the third electrical signal S3 includes not only a component corresponding to the light of the third color but also components corresponding to the light of the first color and the light of the second color. Correction unit 230 may generate the first corrected data C1 corresponding to the light of the first color, the second corrected data C2 corresponding to the light of the second color, and the third corrected data C3 corresponding to the light of the third color, by using the first through third original data D1 through D3. Due to correction unit 230, color interference generated when the pixels 210 have a triple-layer structure may be reduced or eliminated.

ISP 240 may generate first through third color data C1′ through C3′ by performing image signal processing on the first through third corrected data C1 through C3 of the pixels 210. ISP 240 may perform color calibration for generating color data corresponding to actual colors of an object. For example, such image signal processing may include hue adjustment, saturation adjustment, brightness adjustment, correction of color distortion due to lighting, and white balance adjustment. Also, ISP 240 may perform color adjustment as intended, selected, or programmed by a user.

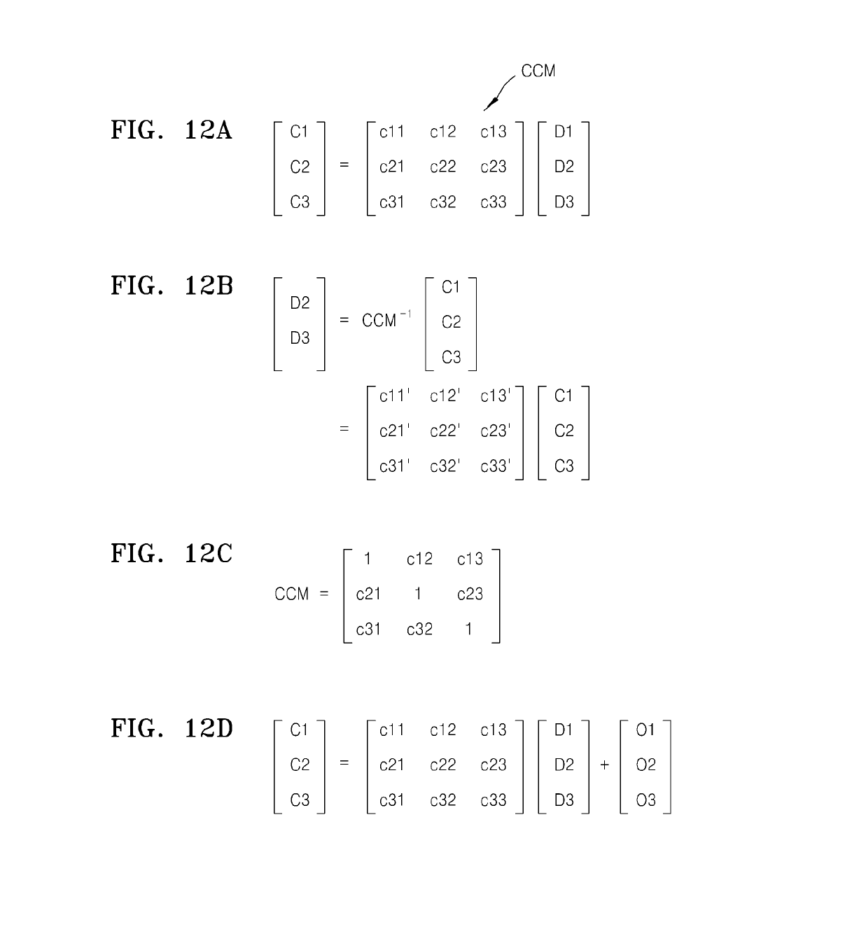

FIGS. 12A through 12D are diagrams for describing an example operation of an embodiment of correction unit 230 illustrated in FIG. 11.

Referring to FIG. 12A, the first through third corrected data C1 through C3 may be generated by multiplying the first through third original data D1 through D3 by a color correction matrix CCM. If a pixel has triple-layer structure as illustrated in FIG. 11, the color correction matrix CCM may be a 3×3 matrix. As illustrated in FIG. 12A, the color correction matrix CCM may have first through ninth coefficients c11, c12, c13, c21, c22, c23, c31, c32, and c33.

The first corrected data C1 may be determined as a sum of: (1) a product of the first coefficient c11 and the first original data D1, (2) a product of the second coefficient c12 and the second original data D2, and (3) a product of the third coefficient c13 and the third original data D3. The second corrected data C2 may be determined as a sum of: (1) a product of the fourth coefficient c21 and the first original data D1, (2) a product of the fifth coefficient c22 and the second original data D2, and (3) a product of the sixth coefficient c23 and the third original data D3. The third corrected data C3 may be determined as a sum of: (1) a product of the seventh coefficient c31 and the first original data D1, (2) a product of the eighth coefficient c32 and the second original data D2, and (3) a product of the ninth coefficient c33 and the third original data D3.

FIG. 12B is a diagram for describing an example method of calculating the first through ninth coefficients c11, c12, c13, c21, c22, c23, c31, c32, and c33 of the color correction matrix CCM. The first through third original data D1 through D3 may be represented as a product of an inverse color correction matrix CCM⁻¹ and the first through third corrected data C1 through C3. The inverse color correction matrix CCM⁻¹ may have first through ninth coefficients c11′, c12′, c13′, c21′, c22′, c23′, c31′, c32′, and c33′.

The first through third original data D1 through D3 have values obtained by respectively quantizing the first through third electrical signals S1 through S3 output from the first through third photoelectric conversion layers L1 through L3. The first through third corrected data C1 through C3 respectively correspond to light of a first color, light of a second color, and light of a third color, which are included in light incident on a pixel.

If monochromatic light of the first color is incident on the pixel, the first corrected data C1 should have a value proportional to the intensity of the monochromatic light, and the second and third corrected data C2 and C3 should have a value 0. Accordingly, the first coefficient c11′ may be determined as a ratio of the value of the first original data D1 to the value of the first corrected data C1, i.e., D1/C1. The fourth coefficient c21′ may be determined as a ratio of the value of the second original data D2 to the value of the first corrected data C1, i.e., D2/C1. The seventh coefficient c31′ may be determined as a ratio of the value of the third original data D3 to the value of the first corrected data C1, i.e., D3/C1.

If monochromatic light of the second color is incident on the pixel, the second corrected data C2 should have a value proportional to the intensity of the monochromatic light, and the first and third corrected data C1 and C3 should have a value 0. Accordingly, the second coefficient c12′ may be determined as a ratio of the value of the first original data D1 to the value of the second corrected data C2, i.e., D1/C2. The fifth coefficient c22′ may be determined as a ratio of the value of the second original data D2 to the value of the second corrected data C2, i.e., D2/C2. The eighth coefficient c32′ may be determined as a ratio of the value of the third original data D3 to the value of the second corrected data C2, i.e., D3/C2.

If monochromatic light of the third color is incident on the pixel, the third corrected data C3 should have a value proportional to the intensity of the monochromatic light, and the first and second corrected data C1 and C2 should have a value 0. Accordingly, the third coefficient c13′ may be determined as a ratio of the value of the first original data D1 to the value of the third corrected data C3, i.e., D1/C3. The sixth coefficient c23′ may be determined as a ratio of the value of the second original data D2 to the value of the third corrected data C3, i.e., D2/C3. The ninth coefficient c33′ may be determined as a ratio of the value of the third original data D3 to the value of the third corrected data C3, i.e., D3/C3.

As such, the first through ninth coefficients c11′, c12′, c13′, c21′, c22′, c23′, c31′, c32′, and c33′ of the inverse color correction matrix CCM⁻¹ may be determined. Accordingly, by inverting the inverse color correction matrix CCM⁻¹ μnce again, the first through ninth coefficients c11, c12, c13, c21, c22, c23, c31, c32, and c33 of the color correction matrix CCM may be calculated.

Although an exemplary method of calculating the first through ninth coefficients c11, c12, c13, c21, c22, c23, c31, c32, and c33 of the color correction matrix CCM is described above with reference to FIG. 12B, the first through ninth coefficients c11, c12, c13, c21, c22, c23, c31, c32, and c33 of the color correction matrix CCM may be determined by another method. For example, the first through ninth coefficients c11, c12, c13, c21, c22, c23, c31, c32, and c33 of the color correction matrix CCM may be set, selected, or programmed by a user. Also, the first through ninth coefficients c11, c12, c13, c21, c22, c23, c31, c32, and c33 of the color correction matrix CCM may vary according to a location of a pixel within a pixel array, in order to reduce or eliminate a chromatic aberration effect of a lens.

FIG. 12C shows an example of the color correction matrix CCM. As illustrated in FIG. 12C, diagonal components of the color correction matrix CCM, i.e., the first, fifth, and ninth coefficients c11, c22, and c33, may be set as a value 1. In this case, the number of multipliers may be reduced by three. The diagonal components of the color correction matrix CCM may be set as a value 1 because the ISP 240 may perform color correction again. For example, the ISP 240 includes a digital gain block in order to perform a function such as white balance adjustment. Accordingly, a sum of coefficients in a row of the color correction matrix CCM does not need to be fixed as a value 1.

Referring to FIG. 12D, the correction unit 230 may include an offset matrix for correcting offsets, in addition to the color correction matrix CCM. As illustrated in FIG. 12D, the first through third corrected data C1 through C3 may be generated by multiplying the first through third original data D1 through D3 by the color correction matrix CCM to calculate a product thereof and then adding first through third offset data O1 through O3 to the product. The first through third offset data O1 through O3 are used to correct dark level current.

FIG. 13 is a block diagram of a correction unit 13. Correction unit 13 may be an embodiment of correction unit 230 in FIG. 11.

Referring to FIG. 13, correction unit 9 may include a first correction component 232, a noise reduction unit 234, and a second correction component 236.

Each of first and second correction components 232 and 236 may use the color correction matrix CCM illustrated in FIGS. 12A through 12D. First correction component 232 may generate first through third temporary data D1′ through D3′ by performing primary correction on the first through third original data D1 through D3 by using a first color correction matrix CCM1. Diagonal components of first color correction matrix CCM1 may have values equal to or greater than 1 and equal to or less than 1.5, and absolute values of non-diagonal components of the first color correction matrix CCM1 may be equal to or less than 0.8.

Noise reduction unit 234 may perform noise reduction on the first through third temporary data D1′ through D3′. For noise reduction, a low pass filter may be used. First through third noise-reduced or noise-filtered temporary data D1″ through D3″ may be generated.

Second correction unit 236 may generate the first through third corrected data C1 through C3 by performing secondary correction on the first through third noise-reduced or noise-filtered temporary data D1″ through D3″ by using a second color correction matrix CCM2.

If color correction is performed once, coefficients of a color correction matrix may have values equal to or greater than 2. This means that noise included in the first through third original data D1 through D3 may be amplified. Accordingly, in FIG. 13, it is beneficial that coefficients of the first color correction matrix CCM1 used to perform primary color correction not have values greater than 1.5.

In order to perform low pass filtering for noise reduction, data of a pixel to be filtered and adjacent pixels of the pixel may be required. Accordingly, original data of all pixels may be stored in a storage unit and then noise reduction may be performed on all of the pixels. For this, in some embodiments the reduction unit 234 and second correction unit 236 for performing secondary color correction on noise-reduced original data may be included in ISP 240 illustrated in FIG. 11.

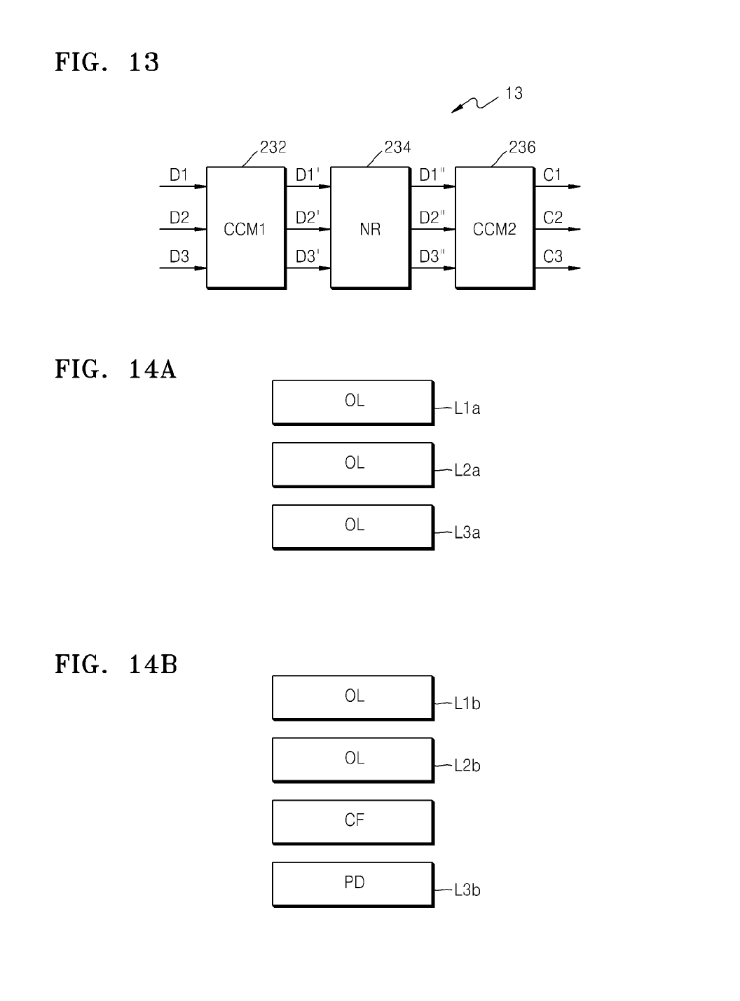

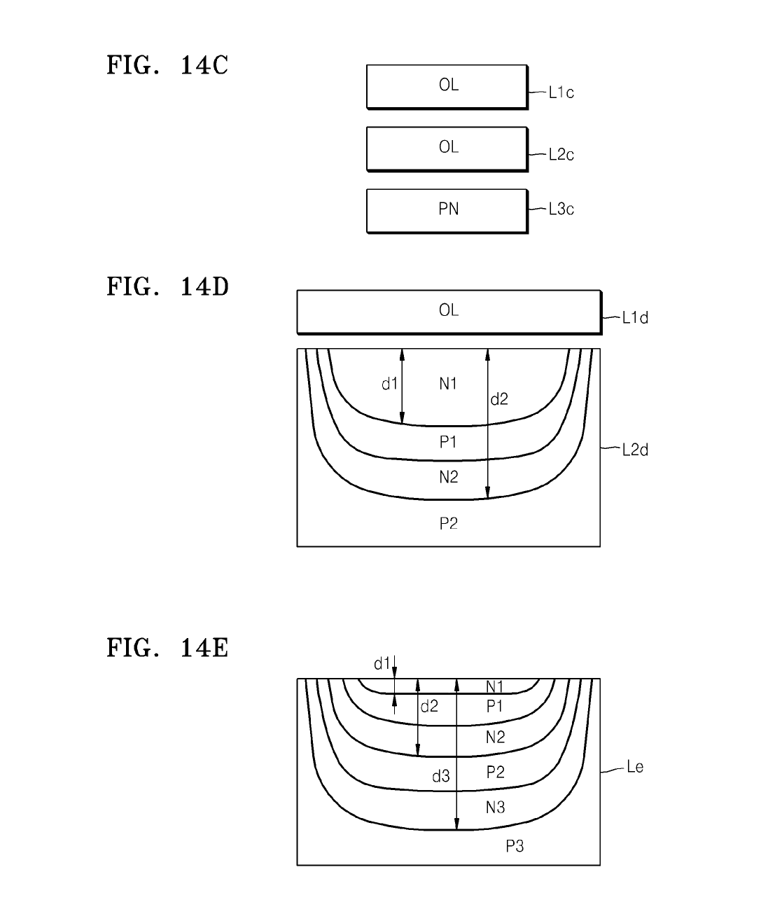

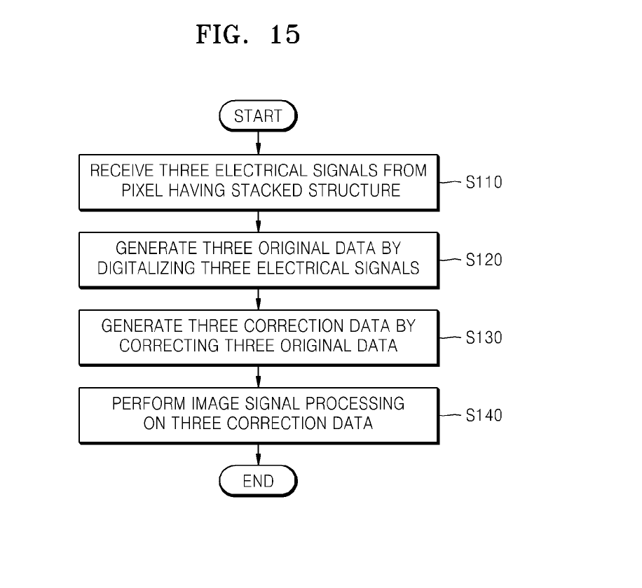

FIGS. 14A through 14E are cross-sectional diagrams of example embodiments of pixels 210 illustrated in FIG. 11, having a stacked structure in a direction in which the light impinges on pixel 210.

Referring to FIG. 14A, a pixel may include first through third photoelectric conversion layers L1 a through L3a each including an organic material. First photoelectric conversion layer L1a may include an organic material having a maximum absorption spectrum in a wavelength range of light of a first color. Second photoelectric conversion layer L2a may include an organic material having a maximum absorption spectrum in a wavelength range of light of a second color. Third photoelectric conversion layer L3a may include an organic material having a maximum absorption spectrum in a wavelength range of light of a third color. In this case, for example, the first color may be green, the second color may be blue, and the third color may be red. As another example, the first color may be green, the second color may be red, and the third color may be blue. As another example, the first color may be red, the second color may be green, and the third color may be blue. As another example, the first color may be red, the second color may be blue, and the third color may be green. As another example, the first color may be blue, the second color may be red, and the third color may be green. However, the inventive concept is not limited thereto.

Each of first through third photoelectric conversion layers L1a through L3a is substantially the same as the first photoelectric conversion layer L1 a illustrated in FIG. 7A, and thus a detailed description thereof is not repeatedly provided here.

Referring to FIG. 14B, a pixel may include first and second photoelectric conversion layers L1b and L2b each including an organic material, a color filter CF, and a third photoelectric conversion layer L3b formed as a semiconductor substrate including a photo diode.

First photoelectric conversion layer L1b includes an organic material for absorbing light of a first color more than light of a second color and light of a third color. That is, first photoelectric conversion layer L1b includes an organic material having a maximum absorption spectrum in a wavelength range of the light of the first color. First photoelectric conversion layer L1b is substantially the same as one of first and second photoelectric conversion layers L1a and L2a illustrated in FIG. 8A, and thus a detailed description thereof is not repeatedly provided here.

Second photoelectric conversion layer L2b includes an organic material for absorbing the light of the second color more than the light of the first color and the light of the third color. That is, second photoelectric conversion layer L2b includes an organic material having a maximum absorption spectrum in a wavelength range of the light of the second color. Second photoelectric conversion layer L2b is substantially the same as one of first and second photoelectric conversion layers L1a and L2a illustrated in FIG. 8A, and thus a detailed description thereof is not repeatedly provided here.

Color filter CF may transmit only light of a certain wavelength band and may block light of the other wavelength bands. For example, color filter CF may transmit at least one of red light, green light, blue light, infrared light, and ultraviolet light, and may block the others. In the current embodiment, color filter CF may transmit only the light of the third color, and may block the light of the first color and the light of the second color.

Third photoelectric conversion layer L3b includes a photo diode formed in a semiconductor substrate. The photo diode may be formed, for example, by injecting n-type ions into a p-type semiconductor substrate. The photo diode absorbs the light of the third color transmitted through the color filter CF, and emits charges.

Referring to FIG. 14C, a pixel may include first and second photoelectric conversion layers L1c and L2c each including an organic material, and a third photoelectric conversion layer L3c formed as a semiconductor substrate including a PN junction structure. first photoelectric conversion layer L1c includes an organic material for absorbing light of a first color more than light of a second color and light of a third color. That is, first photoelectric conversion layer L1c includes an organic material having a maximum absorption spectrum in a wavelength range of the light of the first color. Second photoelectric conversion layer L2c includes an organic material for absorbing the light of the second color more than the light of the first color and the light of the third color. That is, second photoelectric conversion layer L2c includes an organic material having a maximum absorption spectrum in a wavelength range of the light of the second color. First and second photoelectric conversion layers L1c and L2c are each substantially the same as one of first and second photoelectric conversion layers L1 a and L2a illustrated in FIG. 8A, and thus detailed descriptions thereof are not repeatedly provided here.

Third photoelectric conversion layer L3c includes a PN junction structure formed in a semiconductor substrate. Third photoelectric conversion layer L3c includes the PN junction structure at a first depth from a surface of the semiconductor substrate, and the first depth may vary according to the light of the third color. The first depth is determined according to a depth to which the light of the third color is absorbed into the semiconductor substrate. In general, if a wavelength of light is long, a depth to which the light is absorbed into the semiconductor substrate is large.

For example, if the third color is blue, third photoelectric conversion layer L3c may have the PN junction structure about 0.2 μm below the surface of the semiconductor substrate. If the third color is green, third photoelectric conversion layer L3c may have the PN junction structure about 0.6 μm below the surface of the semiconductor substrate. If the third color is red, third photoelectric conversion layer L3c may have the PN junction structure about 2.0 μm below the surface of the semiconductor substrate

Referring to FIG. 14D, a pixel may include a first photoelectric conversion layer L1d including an organic material, and a second photoelectric conversion layer L2d including a semiconductor substrate in which two PN junction structures are formed.

First photoelectric conversion layer L1d includes an organic material having a maximum absorption spectrum in a wavelength range of light of a first color. First photoelectric conversion layer L1d is substantially the same as one of first and second photoelectric conversion layers L1a and L2a illustrated in FIG. 8A, and thus a detailed description thereof is not repeatedly provided here.

Second photoelectric conversion layer L2d includes first and second PN junction structures formed in a semiconductor substrate. Second photoelectric conversion layer L2d includes the first PN junction structure formed at a first depth d1 from a surface of the semiconductor substrate. The first depth d1 may be determined according to a depth to which light of a second color is absorbed into the semiconductor substrate. The second photoelectric conversion layer L2d includes the second PN junction structure formed at a second depth d2 from the surface of the semiconductor substrate. The second depth d2 may be determined according to a depth to which light of a third color is absorbed into the semiconductor substrate. In general, if a wavelength of light is long, a depth to which the light is absorbed into the semiconductor substrate is large.

Accordingly, if the first color is red, the first depth d1 may be determined as a depth to which blue light is absorbed into the semiconductor substrate, and the second depth d2 may be determined as a depth to which green light is absorbed into the semiconductor substrate. That is, the first depth d1 may be about 0.2 μm, and the second depth d2 may be about 0.6 μn. If the first color is green, the first depth d1 may be determined as a depth to which blue light is absorbed into the semiconductor substrate, and the second depth d2 may be determined as a depth to which red light is absorbed into the semiconductor substrate. That is, the first depth d1 may be about 0.2 μm, and the second depth d2 may be about 2.0 μn. If the first color is blue, the first depth d1 is determined as a depth to which green light is absorbed into the semiconductor substrate, and the second depth d2 is determined as a depth to which red light is absorbed into the semiconductor substrate. That is, the first depth d1 may be about 0.6 μm, and the second depth d2 may be about 2.0 μn.

Referring to FIG. 14E, a pixel may include a photoelectric conversion layer Le including a semiconductor substrate in which three PN junction structures are formed.

The photoelectric conversion layer Le includes first through third PN junction structures formed in a semiconductor substrate. The photoelectric conversion layer Le includes the first PN junction structure formed at a first depth d1 from a surface of the semiconductor substrate, the second PN junction structure formed at a second depth d2 from the surface of the semiconductor substrate, and the third PN junction structure formed at the third depth d3 from the surface of the semiconductor substrate. The first depth d1 may be determined according to a depth to which light of a first color is absorbed into the semiconductor substrate. The second depth d2 may be determined according to a depth to which light of a second color is absorbed into the semiconductor substrate. The third depth d3 may be determined according to a depth to which light of a third color is absorbed into the semiconductor substrate. In general, if a wavelength of light is long, a depth to which the light is absorbed into the semiconductor substrate is large. As such, the first color is blue, the second color is green, and the third color is red. Accordingly, the first depth d1 may be about 0.2 μm, the second depth d2 may be about 0.6 μm, and the third depth d3 may be about 2.0 μm.

FIG. 15 is a flowchart of an image processing method. Referring to FIG. 15, three electrical signals are received from pixels having a stacked structure (S110). An image sensor includes an array of the pixels. According to the current embodiment, the pixels have a stacked structure in which three photoelectric conversion layers are stacked on one another.

Three original data are generated by digitizing the three electrical signals (S120). The three original data are generated by individually digitizing the three electrical signals output from each pixel.

Three corrected data are generated by correcting the three original data (S130). The three corrected data are generated by performing color correction on the three original data generated in operation S120. In operation S130, the color correction matrix CCM illustrated in FIGS. 12A through 12D may be used. For example, first corrected data is generated by using first through third original data. Second corrected data is also generated by using the first through third original data, and third corrected data is also generated by using the first through third original data.

Operation S130 may include primary color correction, noise reduction, and secondary color correction according to the embodiment illustrated in FIG. 13. Primary color correction may be performed on the three original data by using a first color correction matrix. Consequently, three temporary data may be generated. Low pass filtering for noise reduction may be performed on the three temporary data. Then, secondary color correction may be performed on the three noise-reduced temporary data by using a second color correction matrix.

Image signal processing is performed on the three corrected data (S140). In operation S140, hue correction, brightness correction, saturation correction, white balance adjustment, correction of color shift due to lighting, etc. may be performed. For image signal processing, the three corrected data may be stored in a storage unit of an ISP.

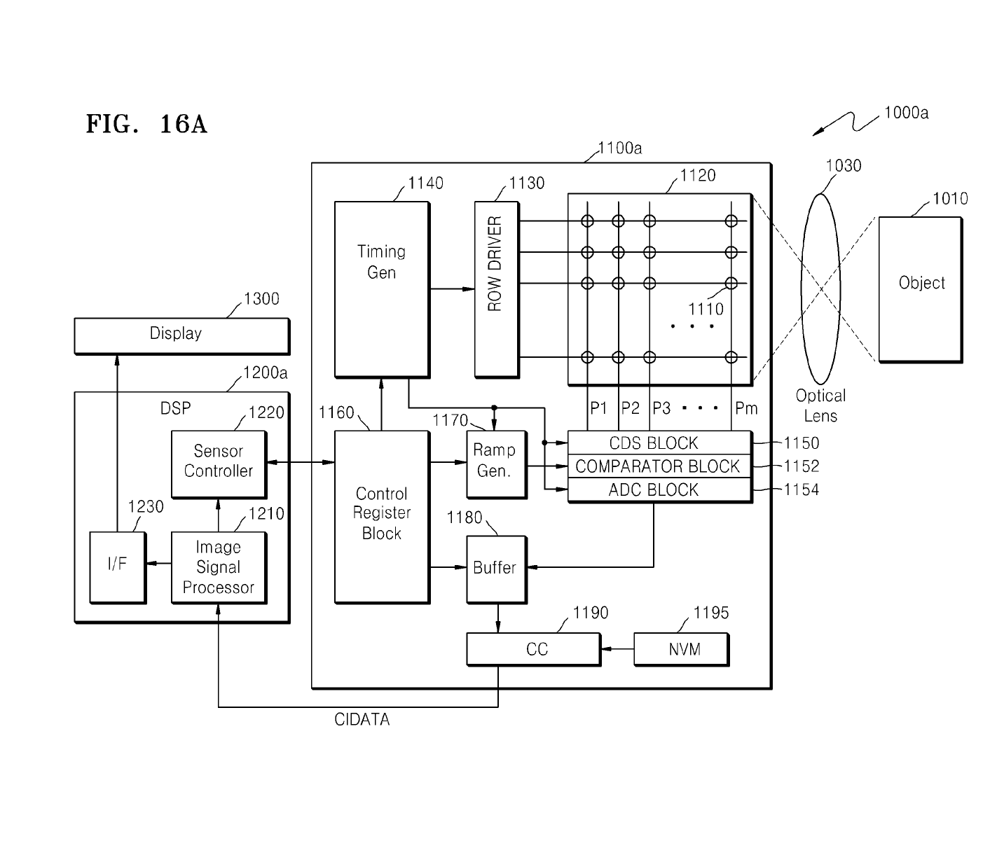

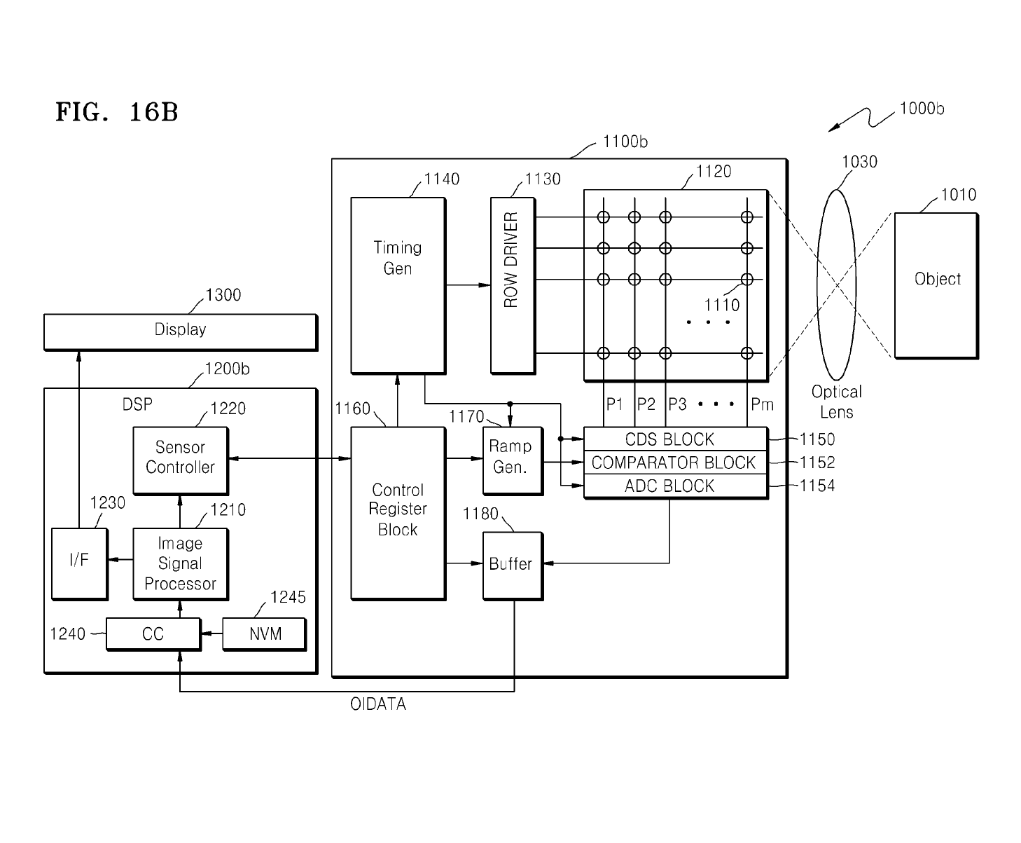

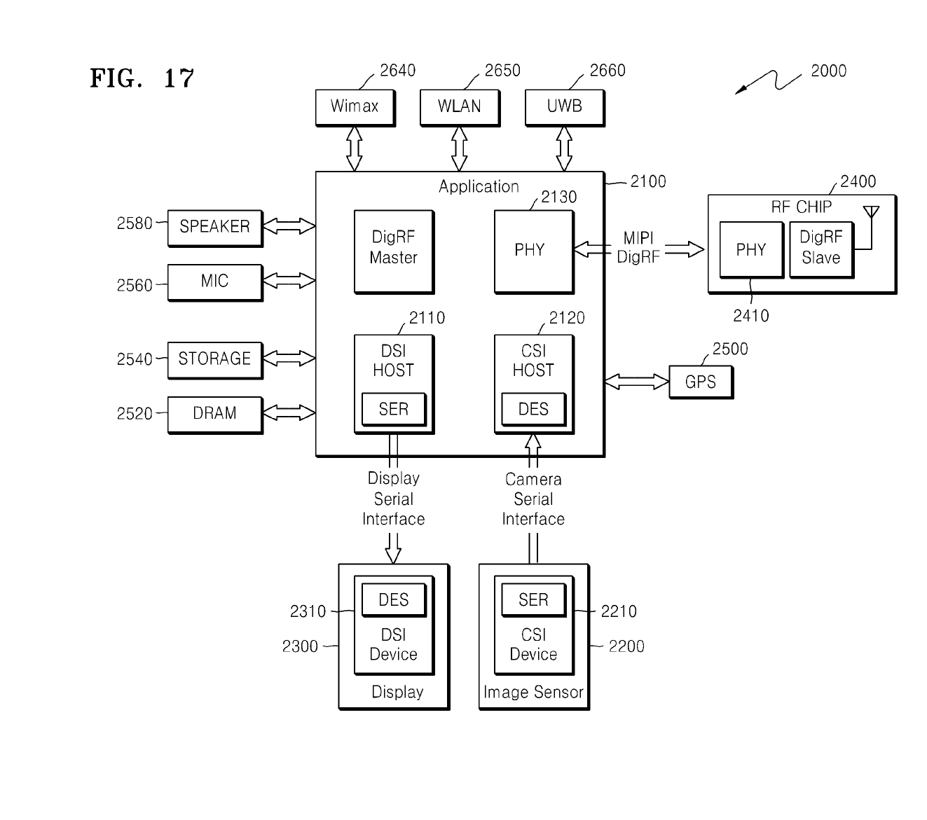

FIG. 16A is a block diagram of an image processing apparatus 1000a.

Referring to FIG. 16A, the image processing apparatus 1000a may be formed as a portable device such as a digital camera, a mobile phone, a smartphone, or a tablet personal computer (PC).

Image processing apparatus 1000a includes an optical lens 1030, an image sensor 1100a, a digital signal processor 1200a, and a display 1300.

Image sensor 1100a generates corrected image data CIDATA of an image of an object 1010, which is obtained or captured through optical lens 1030. For example, image sensor 1100a may be formed as a complementary metal-oxide-semiconductor (CMOS) image sensor.

image sensor 1100a includes a pixel array 1120, a row driver 1130, a timing generator 1140, a CDS block 1150, a comparator block 1152, and an analog-digital conversion (ADC) block 1154, a control register block 1160, a ramp signal generator 1170, and a buffer 1180.

Pixel array 1120 includes a plurality of pixels 1110 aligned in a matrix having m columns, where m is a natural number. As described above, each of the pixels 1110 includes at least two photoelectric conversion layers stacked on one another in a direction in which the light impinges on the pixel, and outputs at least two electrical signals.

Row driver 1130 outputs to pixel array 1120 a plurality of control signals TG, RG, SEL, and TG2 for controlling operation of each of pixels 1110, under the control of timing generator 1140.

Timing generator 1140 controls operations of row driver 1130, CDS block 1150, ADC block 1154, and ramp signal generator 1170, under the control of control register block 1160.

CDS block 1150 performs CDS individually on pixel electrical signals output from the plurality of columns of pixel array 1120. Although the output from each column is illustrated in FIG. 16A as one line, P1 through Pm, it should be understood that each line corresponds to the number of electrical signals output from one pixel 1110. That is, if one pixel 1110 outputs three electrical signals, the number of pixel electrical signals output from one column is also three, and the total number of electrical signals output from pixel array 1120 is 3*m

Comparator block 1152 compares each of the pixel electrical signals output from CDS block 1150 to a ramp signal output from the ramp signal generator 1170, and outputs a plurality of comparator signals.

ADC block 1154 converts the comparator signals output from comparator block 1152, into a plurality of original data (i.e., digital data), and outputs the original data to buffer 1180.

Control register block 1160 controls operations of timing generator 1140, ramp signal generator 1170, and buffer 1180, by the control of digital signal processor 1200a.

Buffer 1180 outputs the original data output from ADC block 1154 to the color correction unit 1190.

Color correction unit 1190 generates a plurality of corrected data based on the original data by using a color correction matrix. Coefficients of the color correction matrix may be stored in a non-volatile memory 1195, and may vary according to a setup, selection, or programming of a user and/or according to locations of pixels 1110 within array 1120 whose data is being corrected. Color correction unit 1190 transmits the corrected image data CIDATA including the corrected data, to digital signal processor 1200a.

Digital signal processor 1200a includes an ISP 1210, a sensor controller 1220, and an interface 1230.

ISP 1210 controls sensor controller 1220 and interface 1230 for controlling control register block 1160. According to one embodiment, image sensor 1100a and digital signal processor 1200a may be formed or packaged together as one package, for example, a multi-chip package. According to another embodiment, image sensor 1100a and ISP 1210 may be formed or packaged together as one package, for example, a multi-chip package.

ISP 1210 processes the corrected image data CIDATA transmitted from color correction unit 1190, and transmits the processed image data to interface 1230. If pixels 1110 have a double-layer structure, the corrected image data CIDATA includes image data of only two colors for each pixel 1110, and ISP 1210 generates image data of the other color by performing color interpolation.

Sensor controller 1220 generates various control signals for controlling control register block 1160, under the control of the ISP 1210.

Interface 1230 transmits the image data processed by ISP 1210 to display 1300. Display 1300 displays the image data output from interface 1230. Display 1300 may be formed as a thin film transistor-liquid crystal display (TFT-LCD), a light emitting diode (LED) display, an organic LED (OLED) display, an active-matrix OLED (AMOLED) display, or other display employing any suitable technology.

FIG. 16B is a block diagram of an image processing apparatus 1000b according to another embodiment.

Referring to FIG. 16B, image processing apparatus 1000b is illustrated. Image processing apparatus 1000b is similar to image processing apparatus 1000a illustrated in FIG. 16A, and only different features therebetween will be described here without repeatedly describing the same features therebetween. Although the image processing apparatus 1000a includes color correction unit 1190 and non-volatile memory 1195 for generating the corrected data by using the original data, in image sensor 1100a, image processing apparatus 1000b includes a color correction unit 1240 and a non-volatile memory 1245 in a digital signal processor 1200b.

In more detail, buffer 1180 of an image sensor 1100b transmits to digital signal processor 1200b original image data OIDATA including a plurality of original data output from ADC block 1154.

Digital signal processor 1200b includes ISP 1210, sensor controller 1220, interface 1230, color correction unit 1240, and non-volatile memory 1245.

Color correction unit 1240 receives the original image data OIDATA output from buffer 1180. Color correction unit 1240 generates a plurality of corrected data based on the original data by using a color correction matrix. Coefficients of the color correction matrix may be stored in non-volatile memory 1245, and may vary according to a setup, selection, or programming of a user and/or according to locations of pixels 1110 within array 1120 whose data is being corrected. Color correction unit 1240 transmits the corrected data to ISP 1210.

ISP 1210 processes the corrected data output from color correction unit 1240 and transmits the processed corrected data to the interface 1230.

FIG. 17 is a block diagram of an image processing apparatus 2000.

Referring to FIG. 17, image processing apparatus 2000 may be formed as an image processing apparatus capable of using or supporting the mobile industry processor interface (MIPI®), for example, a portable device such as a personal digital assistant (PDA), a portable media player (PMP), a mobile phone, a smartphone, or a tablet PC.

Image processing apparatus 2000 includes an application processor 2100, an image sensor 2200, and a display 2300.

A camera serial interface (CSI) host 2120 included in the application processor 2100 may serially communicate with a CSI device 2210 of image sensor 2200 via a CSI. According to an embodiment of the inventive concept, CSI host 2120 may include a deserializer (DES), and CSI device 2210 may include a serializer (SER).

Image sensor 2200 may refer to the image sensor of the image processing apparatus described above in relation to FIGS. 1 and 13. For example, image sensor 2200 may include the image sensor 1100a or 1100b illustrated in FIG. 16A or 16B.

A display serial interface (DSI) host 2110 included in application processor 2100 may serially communicate with a DSI device 2310 of display 2300 via a DSI. According to one embodiment, DSI host 2110 may include an SER, and the DSI device 2310 may include a DES.

Image processing apparatus 2000 may further include a radio-frequency (RF) chip 2400 communicating with application processor 2100. A physical layer (PHY) 2130 of image processing apparatus 2000 and a PHY 2410 of RF chip 2400 may exchange data according to the MIPI digital radio frequency (DigRF).

Image processing apparatus 2000 may include a global positioning system (GPS) receiver 2500, a memory 2520 such as a dynamic random access memory (DRAM), a data storage device 2540 such as a non-volatile memory, e.g., a NAND flash memory, and a microphone (mic) 2560 and/or a speaker 2580.

Also, image processing apparatus 2000 may communicate with an external device by using at least one communication protocol (or communication standard), for example, ultra-wideband (UWB) 2660, wireless local area network (WLAN) 2650, worldwide interoperability for microwave access (WiMAX) 2640, or long term evolution (LTE).

While the inventive concept has been particularly shown and described with reference to exemplary embodiments thereof, it will be understood that various changes in form and details may be made therein without departing from the spirit and scope of the following claims.

1. An image processing apparatus comprising:
a first pixel comprising:
a first photoelectric conversion layer for outputting a first electrical signal in response to received incident light, including light of a first color, light of a second color, and light of a third color; and
a second photoelectric conversion layer disposed under the first photoelectric conversion layer and for outputting a second electrical signal in response to light transmitted through the first photoelectric conversion layer;
a digitization unit for generating first original data by digitizing the first electrical signal and generating second original data by digitizing the second electrical signal; and
a correction unit for generating first corrected data corresponding to the light of the first color and second corrected data corresponding to the light of the second color, by respectively correcting the first original data and the second original data.

2. The image processing apparatus of claim 1, further comprising an interpolation unit for generating interpolation data corresponding to the light of the third color by using a color interpolation method, to generate pixel data of the first pixel having the first corrected data, the second corrected data, and the interpolation data.

3. The image processing apparatus of claim 2, further comprising a signal processing unit for performing image processing on the first corrected data, the second corrected data, and the interpolation data of the first pixel.

4. The image processing apparatus of claim 1, wherein the correction unit generates the first corrected data and the second corrected data by multiplying the first original data and the second original data by a color correction matrix of 2×2.

5. The image processing apparatus of claim 4, wherein coefficients of the color correction matrix are stored in a non-volatile memory.

6. The image processing apparatus of claim 4, wherein coefficients of the color correction matrix are variable by a user.

7. The image processing apparatus of claim 4, further comprising a pixel array comprising the first pixel,
wherein coefficients of the color correction matrix vary according to a location of the first pixel in the pixel array.

8. The image processing apparatus of claim 4, wherein coefficients of the color correction matrix are determined in such a way that, when monochromatic light of the first color is incident on the first pixel, the second corrected data has a value 0, and that, when monochromatic light of the second color is incident on the first pixel, the first corrected data has a value 0.

9. The image processing apparatus of claim 4, wherein diagonal components of the color correction matrix have a value 1.

10. The image processing apparatus of claim 1, wherein the first corrected data is determined as a sum of: (1) a product of the first original data and a first coefficient, (2) a product of the second original data and a second coefficient, and (3) a third coefficient, and
wherein the second corrected data is determined as a sum of: (1) a product of the first original data and a fourth coefficient, (2) a product of the second original data and a fifth coefficient, and (3) a sixth coefficient.

11. The image processing apparatus of claim 1, wherein the first photoelectric conversion layer comprises an organic material for absorbing the light of the first color more than the light of the second color and the light of the third color.

12. The image processing apparatus of claim 1, wherein the second photoelectric conversion layer comprises an organic material for absorbing the light of the second color more than the light of the first color and the light of the third color.

13. The image processing apparatus of claim 1, wherein the first pixel further comprises a color filter layer between the first photoelectric conversion layer and the second photoelectric conversion layer for transmitting the light of the second color and rejecting light of the first color and the third color, and
wherein the second photoelectric conversion layer comprises a photo diode in a semiconductor substrate.

14. The image processing apparatus of claim 1, wherein the second photoelectric conversion layer comprises a PN junction structure formed at a first depth from a surface of a semiconductor substrate, and
wherein the first depth corresponds to a depth to which the light of the second color is absorbed into the semiconductor substrate.

15. The image processing apparatus of claim 1, further comprising a second pixel comprising:
a third photoelectric conversion layer for outputting a third electrical signal by receiving the incident light; and
a fourth photoelectric conversion layer disposed under the third photoelectric conversion layer and for outputting a fourth electrical signal by receiving light transmitted through the third photoelectric conversion layer,
wherein the digitization unit generates third original data by digitizing the third electrical signal, and generates fourth original data by digitizing the fourth electrical signal,
wherein the correction unit generates third corrected data and fourth corrected data by respectively correcting the third original data and the fourth original data, and
wherein the third corrected data is data corresponding to the light of the first color, and the fourth corrected data is data corresponding to the light of the third color.

16. The image processing apparatus of claim 15, further comprising a pixel array having a plurality of the first pixel and a plurality of the second pixel, in which the first pixels and the second pixels are alternately aligned.

17. The image processing apparatus of claim 16, further comprising an interpolation unit for generating first interpolation data of each of the first pixels by using the fourth corrected data of the second pixels adjacent to each first pixel, and generating second interpolation data of each of the second pixels by using the second corrected data of the first pixels adjacent to each second pixel,
wherein the first interpolation data corresponds to the light of the third color and the second interpolation data corresponds to the light of the second color.

18. The image processing apparatus of claim 1, wherein the first color is green, and
wherein one of the second color and the third color is red and another is blue.

19. An image processing method, comprising:
receiving two electrical signals from a pixel, the pixel comprising two photoelectric conversion layers stacked on one another;
generating two original data by digitizing the two electrical signals;
converting the two original data into first corrected data and second corrected data respectively corresponding to light of a first color and light of a second color, wherein the light of the first color and the light of the second color are incident on the pixel; and
generating interpolation data corresponding to light of a third color by using a color interpolation method, and thus generating pixel data of the pixel having the first corrected data, the second corrected data, and the interpolation data.

20. The image processing method of claim 19, wherein the pixel data of the pixel is generated after the two original data are converted into the first corrected data and the second corrected data.

21. The image processing method of claim 19, further comprising generating first color data, second color data, and third color data by performing color calibration on the first corrected data, the second corrected data, and the interpolation data of the pixel.

22-30. (canceled)
